(19) United States
(12) Patent Application Publication
(10) Pub. No.: US 2026/0136941 A1
(43) Pub. Date: May 14, 2026

(54) SEMICONDUCTOR DEVICE PACKAGE AND METHODS OF MANUFACTURE

(71) Applicant: Taiwan Semiconductor Manufacturing Co., Ltd., Hsinchu (TW)

(72) Inventors: Po-Ching Wu, Hsinchu (TW); Shih-Wei Chen, Hsinchu (TW); Meng-Tsan Lee, Hsinchu (TW); An-Jhih Su, Taoyuan (TW)

(21) Appl. No.: 19/055,809

(22) Filed: Feb. 18, 2025

Related U.S. Application Data
(60) Provisional application No. 63/719,174, filed on Nov. 12, 2024.

(51) Int. Cl. H01L 23/62; H01L 21/56; H01L 23/29; H01L 23/31; H01L 23/367; H01L 23/40; H01L 23/498; H01L 23/538

(52) U.S. Cl. CPC H10W 42/80; H10W 40/22; H10W 40/611; H10W 70/611; H10W 70/65; H10W 74/014; H10W 74/016; H10W 74/131; H10W 74/40; H10W 90/701

(57) ABSTRACT

In an embodiment, a method includes forming a package structure, where forming the package structure includes attaching a plurality of dies to a carrier substrate, performing an encapsulation process to surround the plurality of dies with an encapsulant, and forming a redistribution structure over the plurality of dies and the encapsulant, where the redistribution structure is electrically connected to the plurality of dies, where the redistribution structure has a rectangular shape when seen in a top-down view, where the rectangular shape has first parallel edges having a first width, and second parallel edges having a second width, where at least one of the first width and the second width is greater than 212 mm.

### PRIORITY CLAIM AND CROSS-REFERENCE

This application claims the benefit of U.S. Provisional Application No. 63/719,174, filed on Nov. 12, 2024, entitled “System on Panel”, which application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together to form a functional device. Such processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die, in accordance with some embodiments.

FIGS. 2 through 9 illustrate cross-sectional views of intermediate steps during a process for forming a package structure, in accordance with some embodiments.

FIGS. 10A and 10B illustrate top-down views of package structures, in accordance with some embodiments.

FIGS. 11 through 13 illustrate cross-sectional views of intermediate steps during a process for assembling a system, in accordance with some embodiments.

FIGS. 14 through 19 illustrate cross-sectional views of intermediate steps during a process for forming a package structure, in accordance with some embodiments.

FIGS. 20A and 20B illustrate top-down views of package structures, in accordance with some embodiments.

FIG. 21 illustrates a cross-sectional view of intermediate steps during a process for assembling a system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include methods applied to the formation of a device package (e.g., a system-on-panel (SOP) device) that comprises a redistribution structure that has one or more semiconductor chips bonded to the redistribution structure and one or more package components bonded to a side of the redistribution structure opposing the one or more semiconductor chips. The one or more semiconductor chips may be surrounded by an encapsulant, and the combination of the encapsulant and the redistribution structure may be referred to as a panel. In a top-down view, the panel may have a rectangular shape with four straight edges (e.g., including first parallel edges oriented in a first direction, and second parallel edges oriented in a second direction that is perpendicular to the first direction), wherein a distance between the first parallel edges or the second parallel edges is greater than 252 mm, and wherein a distance between the first parallel edges is up to 510 mm, and wherein a distance between the second parallel edges is up to 515 mm. One or more embodiments disclosed herein may allow for the rectangular shape of the panel to reduce the amount of edge area waste as compared to round wafer formats. The rectangular shape maximizes usable area by eliminating the curved edges present in round wafer formats, thereby enabling more efficient utilization of the panel. In addition, the larger dimensions of the panel may enable the integration of more semiconductor chips and package components in a single package. This increased integration capacity provides greater design flexibility and may reduce or eliminate the use of system-level interconnects between multiple smaller packages. As a result, device performance is enhanced through reduced signal path lengths and improved power delivery for high-performance computing applications.

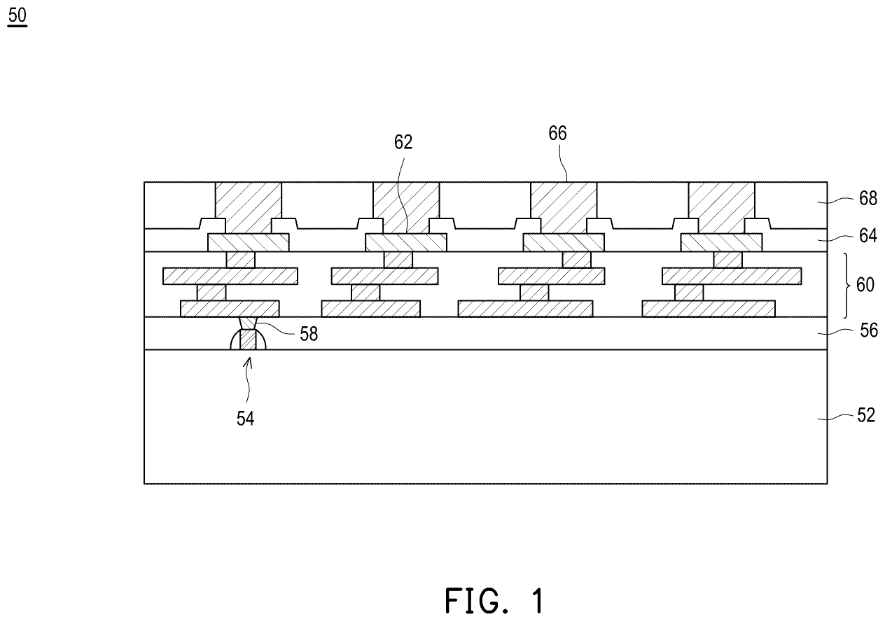

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, a high bandwidth memory (HBM) die, a magnetic random access memory (MRAM) die, etc.), a power management die (e.g., power management integrated circuit (PMIC) die), a radio frequency (RF) die, an input/output (IO) die, a sensor die, a micro-electro-mechanical-system (MEMS) die, a signal processing die (e.g., a digital signal processing (DSP) die or the like), a front-end die (e.g., analog front-end (AFE) dies), a high-performance computing (HPC) die, an artificial intelligence (AI) die, an automotive die, an integrated passive device (IPD) die, a photonic die, an application-specific die (e.g., an application-specific integrated circuit (ASIC), a field-programmable gate array (FPGA), etc.), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like; or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

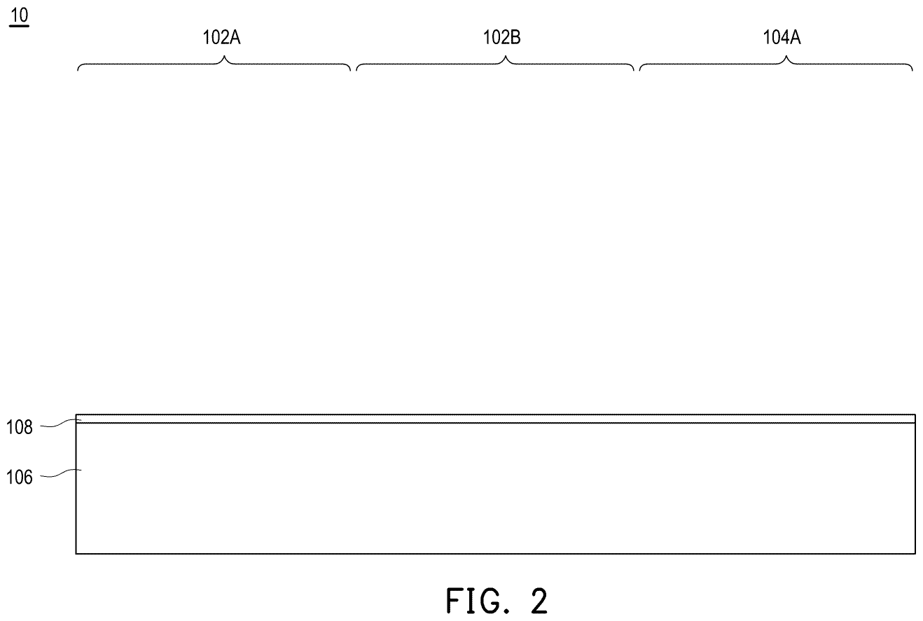

FIGS. 2-9 illustrate cross-sectional views of intermediate steps during a process for forming a package structure 10, in accordance with some embodiments. The package structure 10 may comprise a reconstructed panel having multiple package regions, with one or more of the integrated circuit dies 50 being packaged in each of the package regions. The package regions may include voltage regulation sites 102 and connecting sites 104. Each of the voltage regulation sites 102 may have one or more voltage regulator modules (VRMs) 148 to provide regulated power to the integrated circuit dies 50. Each of the connecting sites 104 may have one or more connectors 158 that enable electrical connections between the package structure 10 and external devices or systems.

In FIG. 2, a carrier substrate 106 is provided, and an adhesive layer 108 is formed on the carrier substrate 106, in accordance with some embodiments. The carrier substrate 106 may be a glass carrier substrate, a ceramic carrier substrate, or the like. The carrier substrate 106 may have a rectangular shape that includes four straight edges (e.g., first parallel edges oriented in a first direction, and second parallel edges oriented in a second direction that is perpendicular to the first direction) when seen in a top-down view, wherein a length of each edge may be greater than 252 mm. The adhesive layer 108 may be removed along with the carrier substrate 106 from the overlying structures that will be formed in subsequent steps. In some embodiments, the adhesive layer 108 is any suitable adhesive, epoxy, die attach film (DAF), or the like, and is applied over the surface of the carrier substrate 106.

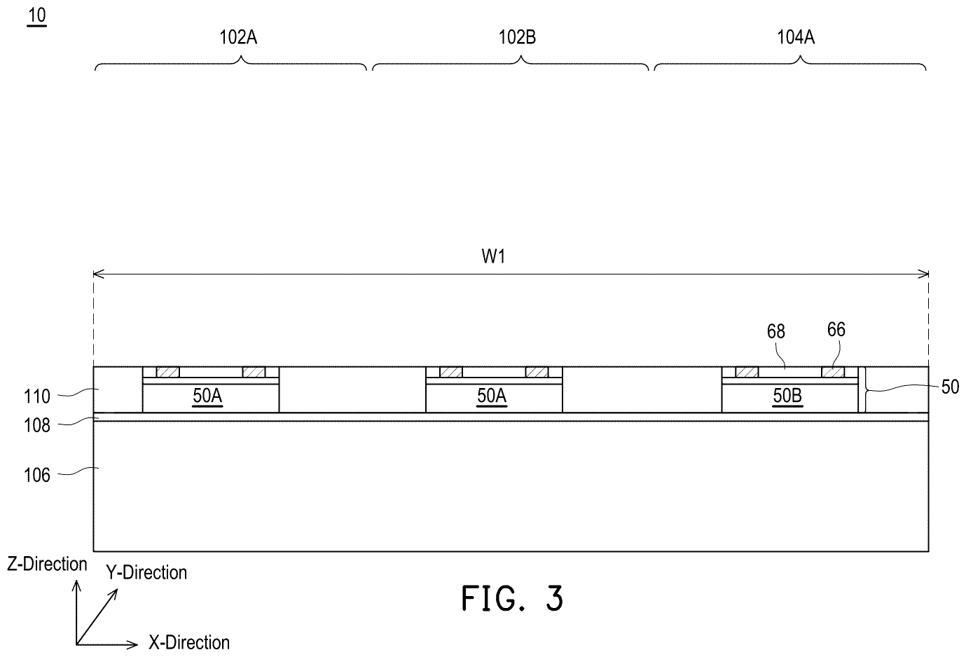

In FIG. 3, integrated circuit dies 50 are attached to the adhesive layer 108, in accordance with some embodiments. A desired type and quantity of integrated circuit dies 50 are attached in each of the voltage regulation sites 102A and 102B and the connecting site 104A, using for example, a pick and place process. In some embodiments, a first type of integrated circuit die, such as a SoC die 50A, or the like, is attached in the voltage regulation sites 102A and 102B, and a second type of integrated circuit die, such as an I/O interface die 50B, or the like, is attached in the connecting site 104A. Although a single integrated circuit die 50 is illustrated in some sites, it should be appreciated that multiple integrated circuit dies may be attached adjacent to one another in some or all of the sites. The arrangement of the voltage regulation sites 102 and the connecting sites 104 shown in FIG. 3 is an illustrative example, and more or fewer voltage regulation sites 102 or connecting sites 104 may be present. In addition, other configurations, arrangements, or layouts of the voltage regulation sites 102 and the connecting sites 104 are possible. Each voltage regulation site 102 may contain more or fewer SoC dies 50A than shown, and each connecting site 104 may include more or fewer I/O interface dies 50B than shown. The SoC dies 50A or I/O interface dies 50B may also have different sizes or shapes than shown.

Referring further to FIG. 3, an encapsulation process may be performed to surround the integrated circuit dies 50 with an encapsulant 110. The encapsulant 110 may comprise a granulated molding compound that includes, for example, epoxy resin particles mixed with silica filler particles. The encapsulant 110 may be applied by compression molding, transfer molding, or the like. In an embodiment, during the encapsulation process, the encapsulant 110 may be heated to a temperature where the epoxy resin particles melt and flow, after which the encapsulant is applied on and around the integrated circuit dies 50 and over the carrier substrate 106. As a result, the encapsulant 110 surrounds the integrated circuit dies 50. Subsequently, the encapsulant 110 may be cured (e.g., by exposing the encapsulant 110 to elevated temperatures). In some embodiments, the encapsulant 110 is formed over the carrier substrate 106 such that the integrated circuit dies 50 are buried or covered, and a planarization process may then be performed on the encapsulant 110 to expose the die connectors 66 of the integrated circuit dies 50. Topmost surfaces of the encapsulant 110, die connectors 66, and/or dielectric layers 68 may be coplanar after the planarization process. The planarization process may include, for example, a chemical-mechanical polish (CMP) process or a grinding process. After the planarization process is performed, in an embodiment, a width W1 of the package structure 10 in a first direction (e.g., the x-direction) may be greater than 252 mm. In an embodiment, a width W2 of the package structure 10 in a second direction (e.g., the y-direction) that is perpendicular to the first direction may be greater than 252 mm. In an embodiment, after the planarization process is performed, the package structure 10 may have a rectangular shape when seen in a top-down view, wherein the rectangular shape includes four straight edges (e.g., first parallel edges oriented in the first direction (e.g., the x-direction) having the width W1, and second parallel edges oriented in the second direction (e.g., the y-direction that is perpendicular to the first direction) having the width W2), wherein each of the widths W1 and the widths W2 of the edges may be greater than 252 mm. In an embodiment, after the planarization process is performed, top surfaces (e.g., including the topmost surfaces of the encapsulant 110, die connectors 66, and/or dielectric layers 68) of the package structure 10 may have a surface area that is greater than 63,504 mm².

Advantages can be achieved by performing the encapsulation process to surround the integrated circuit dies 50 with the encapsulant 110. The encapsulant 110 may comprise a granulated molding compound that includes, for example, epoxy resin particles mixed with silica filler particles. These advantages include allowing for a uniform encapsulation of the integrated circuit dies 50 over larger areas, such as over a top surface of the carrier substrate 106 that may have a rectangular shape that includes four straight edges (e.g., first parallel edges oriented in a first direction, and second parallel edges oriented in a second direction that is perpendicular to the first direction) when seen in a top-down view, wherein a length of each edge may be greater than 252 mm. The use of granulated molding compound may allow for more uniform distribution of the encapsulant 110 to the corners and edges of the carrier substrate 106 that has the rectangular shape, as compared to a liquid molding compound. As a result, package reliability may be enhanced.

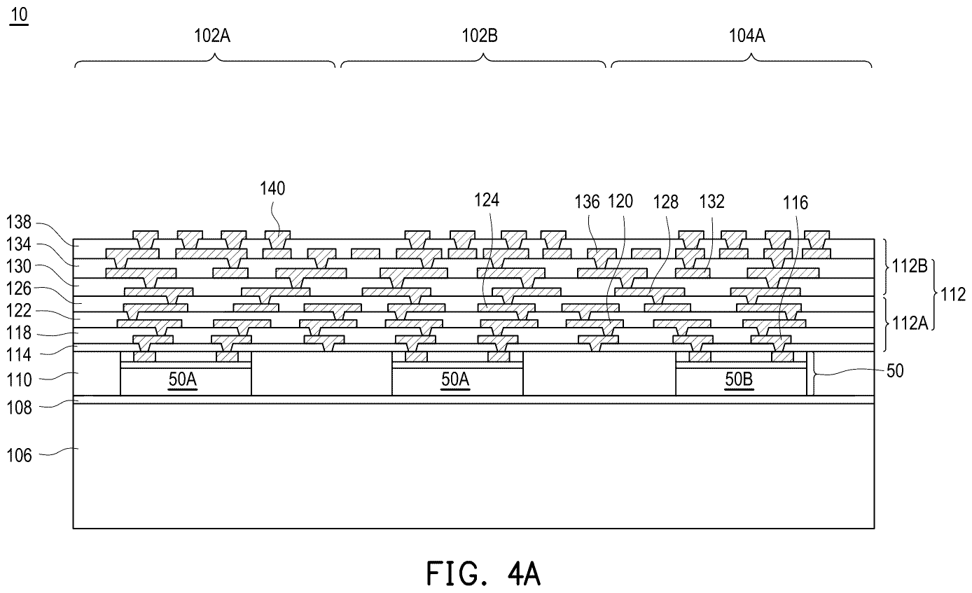

In FIG. 4A, a redistribution structure 112 having a fine-featured portion 112A and a coarse-featured portion 112B is formed over the encapsulant 110 and integrated circuit dies 50, in accordance with some embodiments. The redistribution structure 112 includes metallization patterns, dielectric layers, and under-bump metallurgies (UBMs). The metallization patterns may also be referred to as redistribution layers or redistribution lines. The redistribution structure 112 is shown as an example having six layers of metallization patterns. More or fewer dielectric layers and metallization patterns may be formed in the redistribution structure 112. If fewer dielectric layers and metallization patterns are to be formed, steps and process discussed below may be omitted. If more dielectric layers and metallization patterns are to be formed, steps and processes discussed below may be repeated. The fine-featured portion 112A and coarse-featured portion 112B of the redistribution structure 112 include metallization patterns and dielectric layers of differing sizes.

The coarse-featured portion 112B may have lower resistance compared to the fine-featured portion 112A due to the thickness of the metallization patterns included in the coarse-featured portion 112B and the fine-featured portion 112A. In some embodiments, the coarse-featured portion 112B may be used to route power lines, which may function suitably while having a relatively high resistance. In some embodiments, the fine-featured portion 112A may be used to route signal lines, which may have improved function with a lower resistance. Including both the coarse-featured portion 112B and the fine-featured portion 112A allows for power lines and signal lines to be routed, while minimizing the thickness of the redistribution structure 112.

FIG. 4A shows that the fine-featured portion 112A of the redistribution structure 112 is formed, in accordance with some embodiments. The fine-featured portion 112A of the redistribution structure 112 includes dielectric layers 114, 118, 122, and 126; and metallization patterns 116, 120, and 124. In some embodiments, the dielectric layers 114, 118, 122 and 126 are formed from a same dielectric material, and may be formed to a same thickness or have different thickness. Likewise, in some embodiments, the conductive features of the metallization patterns 116, 120 and 124 are formed from a same conductive material, and may be formed to a same thickness or have different thicknesses.

As an example of forming the fine-featured portion 112A of the redistribution structure 112, the dielectric layer 114 is deposited over the encapsulant 110 and the integrated circuit dies 50. In some embodiments, the dielectric layer 114 is formed of a photo-sensitive material such as polyimide, PBO, BCB, or the like. In an embodiment, the dielectric layer 114 may be formed by performing a slit coating process using, for example, a slit coating apparatus 12 that is shown in a top-down view in FIG. 4B. The slit coating process may include positioning the package structure 10 (e.g., including the carrier substrate 106) on a coating stage 80 of the slit coating apparatus 12, wherein the coating stage 80 is movable (e.g., shown by the arrows A-A) along a first direction by a stage movement mechanism. A slit nozzle 84 may be attached to a movable gantry, where the slit nozzle 84 may be positioned to be above the coating stage 80. The slit nozzle 84 may be movable (e.g., shown by the arrows B-B) along the first direction by a gantry movement mechanism. The photo-sensitive material may be supplied to the slit nozzle 84 by a material pump 86, and dispensed through the slit nozzle 84 while the relative movement between the coating stage 80 and the slit nozzle 84 is precisely controlled to form a uniform dielectric layer 114 over the entire top surface area of the package structure 10, such as over the encapsulant 110 and the integrated circuit dies 50. The slit nozzle 84 may extend across and overlap the entire width of the package structure 10 in a second direction that is perpendicular to the first direction, thereby ensuring complete coverage of the photo-sensitive material over the package structure 10 as the relative movement between the coating stage 80 and the slit nozzle 84 occurs in the first direction. In other embodiments, the dielectric layer 114 may be formed by lamination, CVD, the like, or a combination thereof.

The dielectric layer 114 may then be patterned. The patterning forms openings exposing portions of the die connectors 66 of the integrated circuit dies 50. In an embodiment, when the dielectric layer 114 is a photo-sensitive material, the patterning may be performed by a Laser Direct Imaging (LDI) process using a Laser Direct Imaging (LDI) apparatus, which may directly write the desired pattern without the need of a photomask by exposing the dielectric layer 114 to a laser beam. In an embodiment, data for the desired pattern may be provided to the LDI apparatus in a digital format, and the LDI apparatus may use the data to control the laser beam exposure across a top surface of the dielectric layer 114. In other embodiments, the patterning may be performed using a stepper, where the dielectric layer 114 may be exposed to light through a photomask in stepped increments across the top surface of the package structure 10. After exposure by either the LDI process or by using the stepper, the dielectric layer 114 is developed to form the openings that expose top surfaces of the die connectors 66.

Advantages can be achieved by performing the LDI process using the LDI apparatus to pattern the dielectric layer 114 and to subsequently pattern other dielectric layers of the package structure 10. These may include allowing for complete patterning coverage over larger areas without the need for photomasks, such as over the top surface of the package structure 10, wherein the package structure 10 may have a rectangular shape when seen in a top-down view, wherein the rectangular shape includes four straight edges (e.g., first parallel edges oriented in the first direction (e.g., the x-direction) having the width W1, and second parallel edges oriented in the second direction (e.g., the y-direction that is perpendicular to the first direction) having the width W2), and wherein each of the widths W1 and the widths W2 of the edges may be greater than 252 mm. In addition, alignment issues that may be associated with stepper processes may be eliminated.

In other embodiments, the patterning of the dielectric layer 114 may be performed by etching using, for example, an anisotropic etch process, wherein a photoresist is used as an etch mask. The photoresist may be formed, for example, by using a slit coating process, where the slit coating apparatus 12 (described above) may supply photoresist through the material pump 86 to the slit nozzle 84, which dispenses the photoresist while the relative movement between the coating stage 80 and the slit nozzle 84 is precisely controlled to form a uniform layer of photoresist over the dielectric layer 114. The photoresist may then be patterned using, for example, the LDI process described above, which uses the LDI apparatus to write the desired pattern to the photoresist without the need of a photomask by exposing the photoresist to a laser beam. In an embodiment, data for the desired pattern may be provided to the LDI apparatus in a digital format, and the LDI apparatus may use the data to control the laser beam exposure across a top surface of the photoresist. In other embodiments, the patterning may be performed using a stepper, where the photoresist may be exposed to light through a photomask in stepped increments across the top surface of the package structure 10. After exposure by either the LDI process or by using the stepper, the photoresist is developed to form the patterned photoresist, which is then used as a mask during the anisotropic etching of the dielectric layer 114.

Advantages can be achieved by performing both the slit coating process and the LDI process to form and pattern the photoresist used as an etch mask for the dielectric layer 114, and to form and pattern photoresists used as etch masks for other subsequently formed layers of the package structure 10. These may include allowing for uniform photoresist coating and complete patterning coverage over larger areas, such as over the top surface of the package structure 10, wherein the package structure 10 may have a rectangular shape when seen in a top-down view, wherein the rectangular shape includes four straight edges (e.g., first parallel edges oriented in the first direction (e.g., the x-direction) having the width W1, and second parallel edges oriented in the second direction (e.g., the y-direction that is perpendicular to the first direction) having the width W2), and wherein each of the widths W1 and the widths W2 of the edges may be greater than 252 mm. In addition, the use of the slit coating process eliminates edge thickness variations of the photoresist at corners and edges of the rectangular shape of the package structure 10 during deposition of the photoresist. As a result, patterning of the photoresist can be achieved over the entire top surface of the package structure 10.

The metallization pattern 116 is then formed. The metallization pattern 116 has line portions (also referred to as conductive lines or traces) on and extending along the major surface of the dielectric layer 114, and has via portions (also referred to as conductive vias) extending through the dielectric layer 114 to physically and electrically couple the die connectors 66 of the integrated circuit dies 50. As an example to form the metallization pattern 116, a seed layer is formed over the dielectric layer 114 and in the openings extending through the dielectric layer 114. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by the slit coating process described above, or the like, and may be exposed to a laser beam or light for patterning, using for example, the LDI process or the stepper described above. The pattern of the photoresist corresponds to the metallization pattern 116. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 116. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

The dielectric layer 118 is then deposited on the metallization pattern 116 and dielectric layer 114. The dielectric layer 118 may be formed in a similar manner and of a similar material as the dielectric layer 114. The metallization pattern 120 is then formed. The metallization pattern 120 has line portions on and extending along the major surface of the dielectric layer 118, and has via portions extending through the dielectric layer 118 to physically and electrically couple the metallization pattern 116. The metallization pattern 120 may be formed in a similar manner and of a similar material as the metallization pattern 116.

The dielectric layer 122 is then deposited on the metallization pattern 120 and dielectric layer 118. The dielectric layer 122 may be formed in a similar manner and of a similar material as the dielectric layer 114. The metallization pattern 124 is then formed. The metallization pattern 124 has line portions on and extending along the major surface of the dielectric layer 122, and has via portions extending through the dielectric layer 122 to physically and electrically couple the metallization pattern 120. The metallization pattern 124 may be formed in a similar manner and of a similar material as the metallization pattern 116.

The dielectric layer 126 is deposited on the metallization pattern 124 and dielectric layer 122. The dielectric layer 126 may be formed in a similar manner and of a similar material as the dielectric layer 114.

Advantages can be achieved by performing the slit coating process using the slit coating apparatus 12 that is shown in the top-down view in FIG. 4B to form the dielectric layers 114, 118, 122, and 126 of the fine-featured portion 112A of the redistribution structure 112 over the top surface of the package structure 10 (e.g., comprising the topmost surfaces of the encapsulant 110, die connectors 66, and/or dielectric layers 68), as well as to form subsequent layers of the package structure 10. These advantages include allowing a uniform deposition and complete coverage of materials of the dielectric layers 114, 118, 122, and 126 over a larger area, such as over the top surface of the package structure 10. The package structure 10 may have a rectangular shape when seen in a top-down view, wherein the rectangular shape includes four straight edges (e.g., first parallel edges oriented in the first direction (e.g., the x-direction) having the width W1, and second parallel edges oriented in the second direction (e.g., the y-direction that is perpendicular to the first direction) having the width W2), wherein each of the widths W1 and the widths W2 of the edges may be greater than 252 mm. In addition, the slit coating process may reduce material accumulation and thickness variation that may occurs at corners and edges of the rectangular shape of the package structure 10. As a result, thickness uniformity of the materials of the dielectric layers 114, 118, 122, and 126 is maintained, and reliability of the package structure 10 may be improved.

After the formation of the fine-featured portion 112A of the redistribution structure 112, the coarse-featured portion 112B of the redistribution structure 112 is formed, in accordance with some embodiments. The coarse-featured portion 112B of the redistribution structure 112 includes dielectric layers 130, 134, and 138; and metallization patterns 128, 132, and 136. In some embodiments, the dielectric layers 130, 134, and 138 are formed from a same dielectric material, and are formed to a same thickness, or having different thicknesses. Likewise, in some embodiments, the conductive features of the metallization patterns 128, 132, and 136 are formed from a same conductive material, and are formed to a same thickness, or having different thicknesses.

As an example of forming the coarse-featured portion 112B of the redistribution structure 112, the metallization pattern 128 is formed. The metallization pattern 128 has line portions on and extending along the major surface of the dielectric layer 126, and has via portions extending through the dielectric layer 126 to physically and electrically couple the metallization pattern 124. As an example to form the metallization pattern 128, a seed layer is formed over the dielectric layer 126 and in the openings extending through the dielectric layer 126. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by the slit coating process described above, or the like, and may be exposed to a laser beam or light for patterning, using for example, the LDI process or the stepper described above. The pattern of the photoresist corresponds to the metallization pattern 128. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 128. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

The dielectric layer 130 is then formed on the metallization pattern 128 and dielectric layer 126. In some embodiments, the dielectric layer 130 is formed of Ajinomoto build-up film (ABF), or the like, which may be formed by lamination, or the like. The dielectric layer 130 may then be patterned. The patterning forms openings exposing portions of the metallization pattern 128. The patterning may be performed by etching using, for example, an anisotropic etch process, wherein a photoresist is used as an etch mask. The photoresist may be formed, for example, by using a slit coating process, where the slit coating apparatus 12 (described above) may supply photoresist through the material pump 86 to the slit nozzle 84, which dispenses the photoresist while the relative movement between the coating stage 80 and the slit nozzle 84 is precisely controlled to form a uniform layer of photoresist over the dielectric layer 130. The photoresist may then be patterned using, for example, the LDI process described above, which uses the LDI apparatus to write the desired pattern to the photoresist without the need of a photomask by exposing the photoresist to a laser beam. In an embodiment, data for the desired pattern may be provided to the LDI apparatus in a digital format, and the LDI apparatus may use the data to control the laser beam exposure across a top surface of the photoresist. In other embodiments, the patterning may be performed using a stepper, where the photoresist may be exposed to light through a photomask in stepped increments across the top surface of the package structure 10. After exposure by either the LDI process or by using the stepper, the photoresist is developed to form the patterned photoresist, which is then used as a mask during the anisotropic etching of the dielectric layer 130.

The metallization pattern 132 is then formed. The metallization pattern 132 has line portions on and extending along the major surface of the dielectric layer 130, and has via portions extending through the openings in the dielectric layer 130 to physically and electrically couple the metallization pattern 128. The metallization pattern 132 may be formed in a similar manner and of a similar material as the metallization pattern 128.

The dielectric layer 134 is then formed on the metallization pattern 132 and dielectric layer 130. The dielectric layer 134 may be formed in a similar manner and of a similar material as the dielectric layer 130. The metallization pattern 136 is then formed. The metallization pattern 136 has line portions on and extending along the major surface of the dielectric layer 134, and has via portions extending through the dielectric layer 134 to physically and electrically couple the metallization pattern 132. The metallization pattern 136 may be formed in a similar manner and of a similar material as the metallization pattern 128.

The dielectric layer 138 is then formed on the metallization pattern 136 and dielectric layer 134. In an embodiment, the dielectric layer 138 may be formed in a similar manner and of a similar material as the dielectric layer 130. In an embodiment, the dielectric layer 138 may be formed in a similar manner and of a similar material as the dielectric layer 114.

After the formation of the dielectric layer 138, UBMs 140 are formed for external connection to the redistribution structure 112. The UBMs 140 have bump portions on and extending along the major surface of the dielectric layer 138, and have via portions extending through the dielectric layer 138 to physically and electrically couple the metallization pattern 136. As a result, the UBMs 140 are electrically coupled to the integrated circuit dies 50. In an embodiment, the UBMs 140 may be formed in a similar manner and of a similar material as the metallization pattern 136. In an embodiment, the UBMs 140 may be formed in a similar manner and of a similar material as the metallization pattern 116. In some embodiments, the UBMs 140 have a different size than the metallization patterns 116, 120, 124, 128, 132, and 136.

In an embodiment, the redistribution structure 112 may have a rectangular shape when seen in a top-down view, wherein the rectangular shape of the redistribution structure 112 has four straight outer edges (e.g., first parallel edges of the redistribution structure 112 oriented in the first direction (e.g., the x-direction), and second parallel edges of the redistribution structure 112 oriented in the second direction (e.g., the y-direction that is perpendicular to the first direction)). In an embodiment, each of the first parallel edges may have the width W1 that is greater than 252 mm, and each of the second parallel edges may have the width W2 that is greater than 252 mm. In an embodiment, the width W1 may be up to 510 mm, and the width W2 may be up to 515 mm. In an embodiment, the width W2 may be up to 510 mm, and the width W1 may be up to 515 mm.

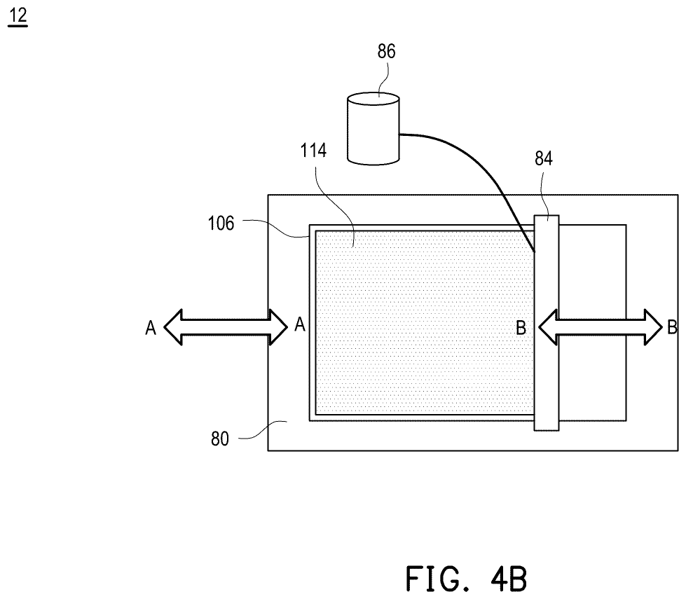

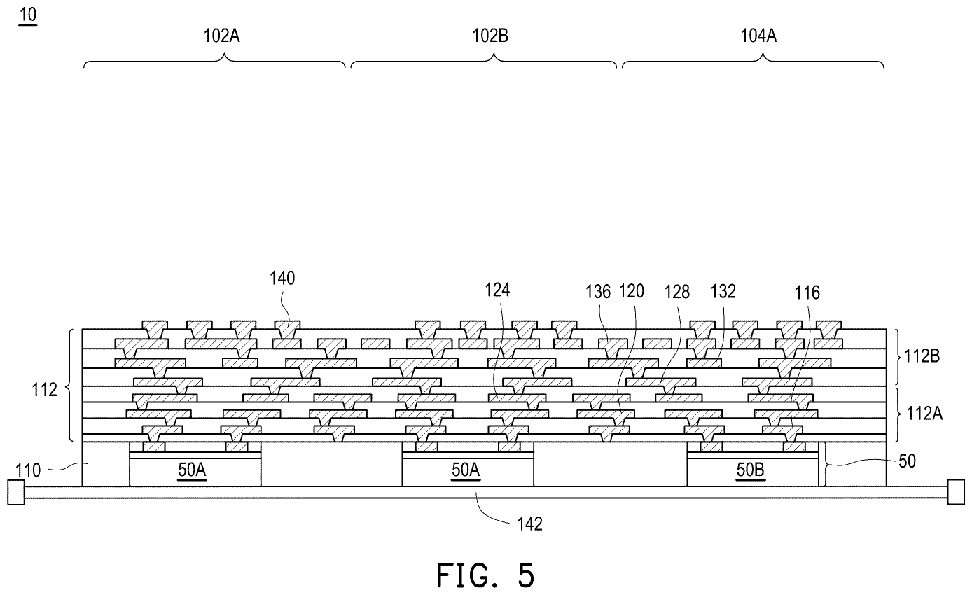

In FIG. 5, a carrier substrate debonding is performed to detach (or “debond”) the carrier substrate 106 from the encapsulant 110 and integrated circuit dies 50. In some embodiments, the debonding includes removing the carrier substrate 106 and adhesive layer 108 by, e.g., a grinding or planarization process, such as a CMP process. After removal, back side surfaces of the integrated circuit dies 50 may be exposed, and the back side surfaces of the encapsulant 110 and integrated circuit dies 50 may be level. The structure is then placed on a tape 142.

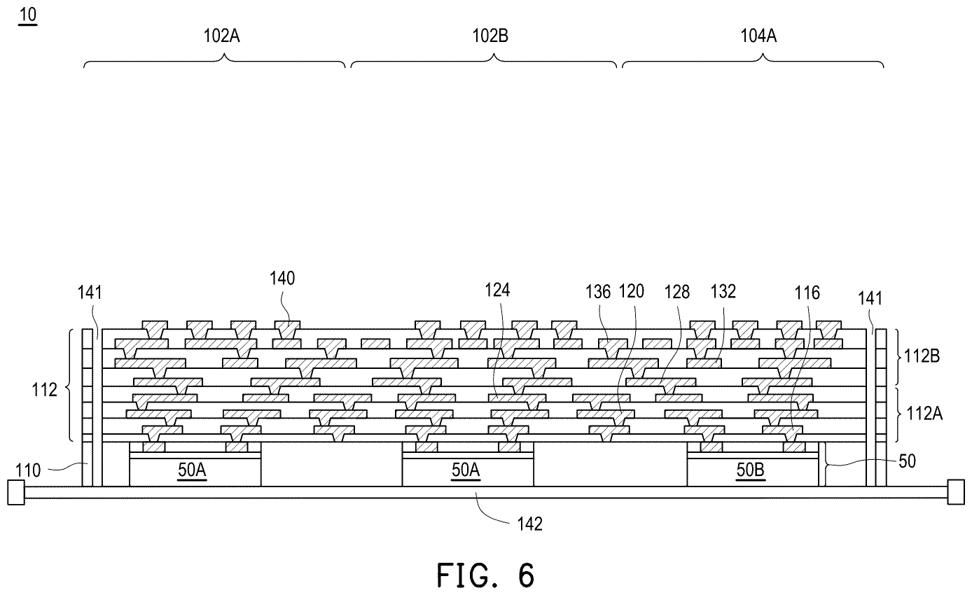

In FIG. 6, screw holes 141 are formed through the package structure 10. For example, the screw holes 141 may extend through the redistribution structure 112 and the encapsulant 110. The screw holes 141 may be formed by a drilling process such as laser drilling, mechanical drilling, or the like. The screw holes 141 may be formed by drilling an outline for the screw holes 141 using a drilling process, and then removing the material separated by the outline, for example. In an embodiment, screws may be subsequently positioned to extend through the screw holes 141 in order to secure the package structure 10 to and/or between other structures.

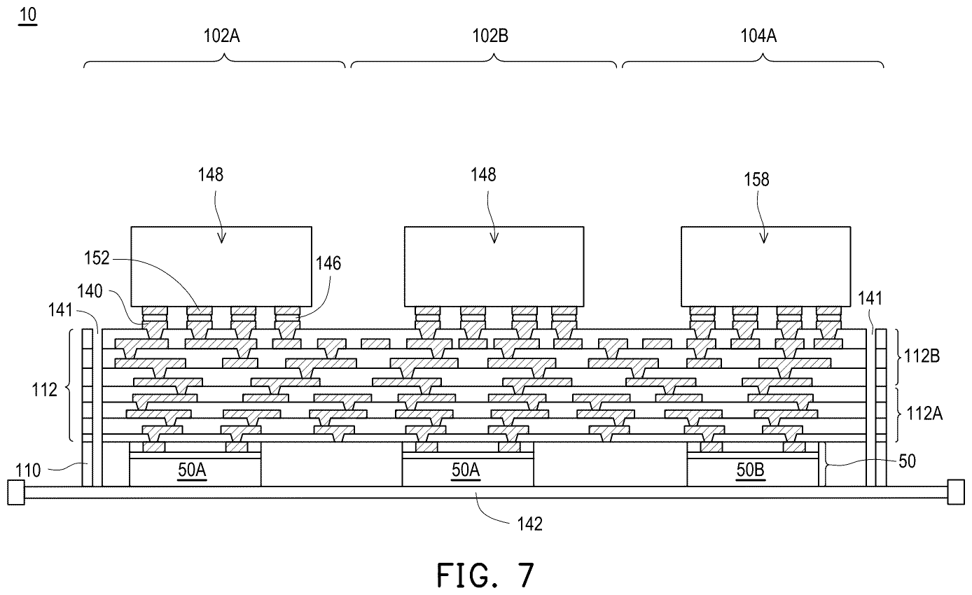

In FIG. 7, conductive connectors 146 are formed on the UBMs 140. The conductive connectors 146 may be ball grid array (BGA) connectors, solder balls, metal pillars, controlled collapse chip connection (C4) bumps, micro bumps, electroless nickel-electroless palladium-immersion gold technique (ENEPIG) formed bumps, electroless nickel-immersion gold technique (ENIG) formed bumps, or the like. The conductive connectors 146 may include a conductive material such as solder, copper, aluminum, gold, nickel, silver, palladium, tin, the like, or a combination thereof. In some embodiments, the conductive connectors 146 are formed by initially forming a layer of solder or solder paste through evaporation, electroplating, printing, solder transfer, ball placement, or the like. Once a layer of solder has been formed on the structure, a reflow may be performed in order to shape the material into the desired bump shapes.

Referring further to FIG. 7, voltage regulator modules (VRMs) 148 and connector 158 may be attached to the redistribution structure 112, in accordance with some embodiments. The VRMs 148 may comprise power management circuitry including inductors, capacitors, and control ICs for converting and regulating voltage levels, and to provide stable and regulated power to the integrated circuit dies 50. The connector 158 may be, for example, high-speed electrical connectors with multiple signal pins and power pins arranged in a predetermined pattern, to allow electrical connections between the package structure 10 and other external devices or to adjacent package structures within a larger system. The VRMs 148 and the connectors 158 include contact pads 152, such as aluminum or copper pads, which are used for physical and electrical connection to the redistribution structure 112. Attaching the VRMs 148 or the connectors 158 may include placing them on the redistribution structure 112 using, e.g., a pick-and-place process, and then reflowing the conductive connectors 146 to physically and electrically couple the contact pads 152 to the UBMs 140. Reflow of the conductive connectors 146 may be performed such that the VRMs 148 and the connectors 158 are simultaneously attached to the redistribution structure 112. In the embodiment shown, a VRM 148 is attached to each of the voltage regulation sites 102A and 102B to provide localized power delivery, and a connector 158 is attached at the connecting site 104A to enable high-speed data transmission and power delivery between the package structure 10 and other external devices or adjacent package structures within a larger system. The arrangement of the VRMs 148 and the connectors 158 shown in FIG. 7 is an illustrative example, and more or fewer VRMs 148 or the connectors 158 may be present. In addition, other configurations, arrangements, or layouts of the VRMs 148 and the connectors 158 are possible.

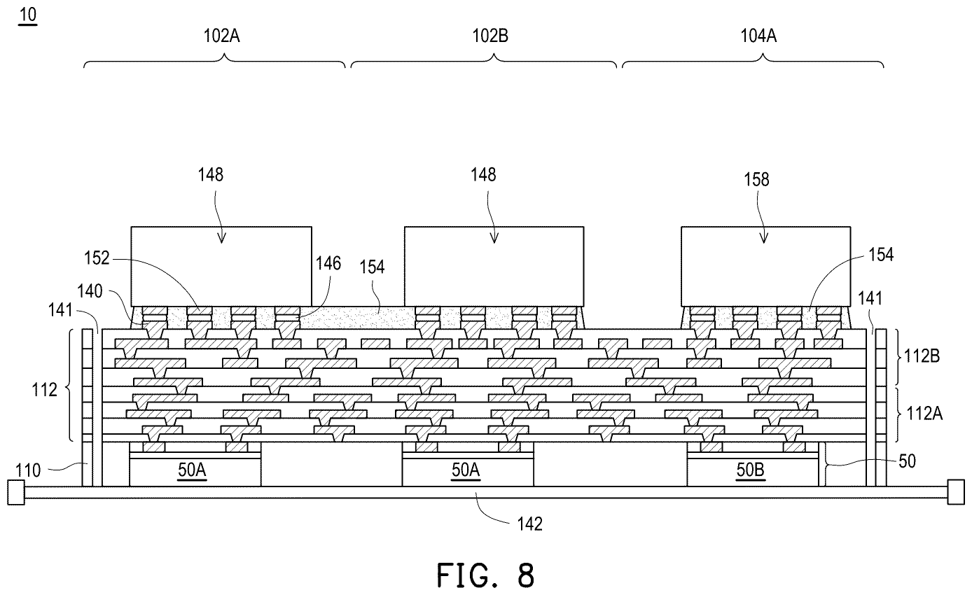

In FIG. 8, an underfill 154 may be formed to fill the gaps between the VRMs 148 and the redistribution structure 112. The underfill 154 may also overlap a portion of the redistribution structure 112 that is disposed between the VRMs 148. The underfill 154 may be formed by a capillary flow process after the VRMs 148 and the connectors 158 are attached, or may be formed by a suitable deposition method before the VRMs 148 and the connectors 158 are attached. In some embodiments, an underfill 154 may also be formed to fill the gap between the connector 158 and the redistribution structure 112.

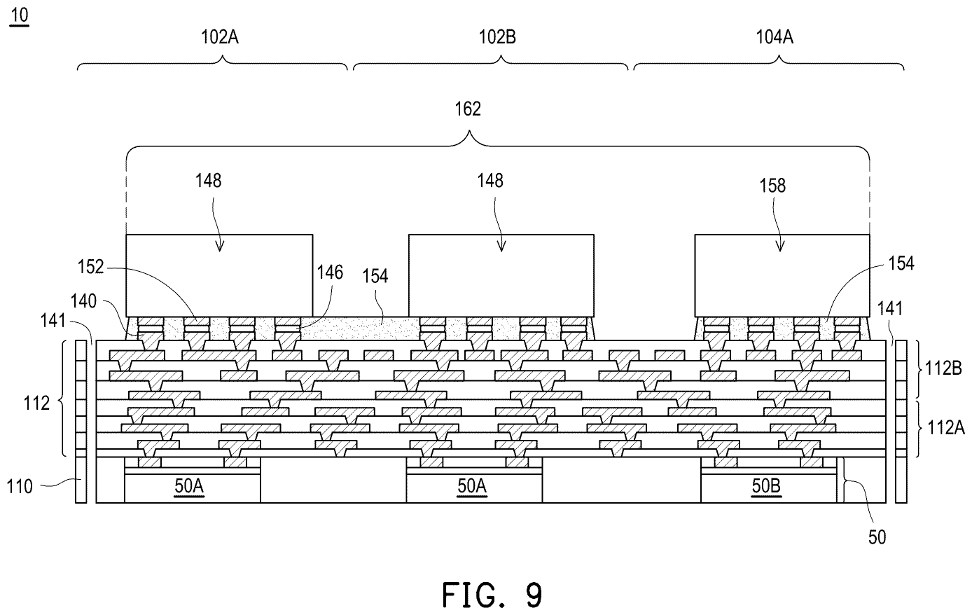

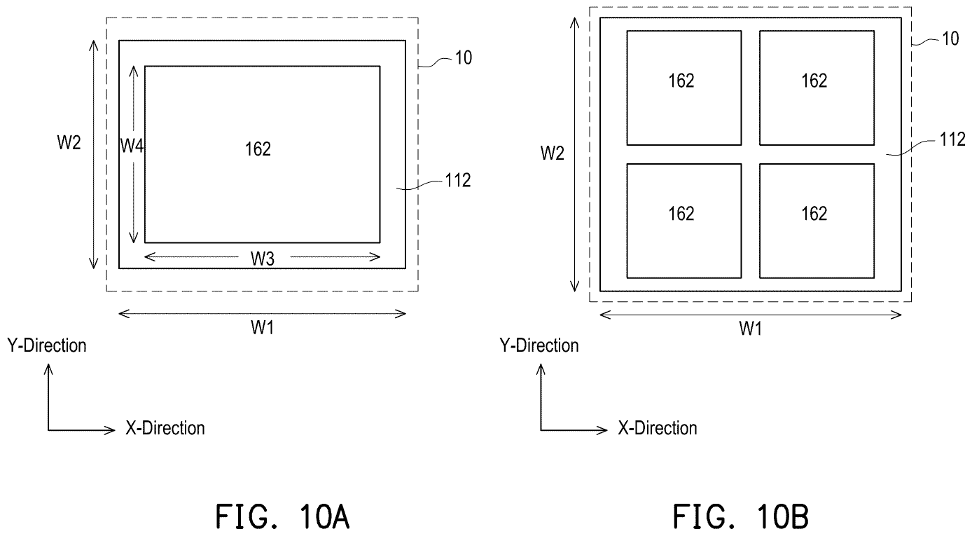

In FIG. 9, after the formation of the underfill 154, the package structure 10 may be removed from the tape 142. The package structure 10 may include a first region 162 within which the integrated circuit dies 50 (which may include logic dies, memory dies, and/or I/O dies) and package components (e.g., the VRMs 148 and the connectors 158) are disposed. As such, the first region 162 functions as an independent system with its own integrated circuit dies 50 (which may include logic dies, memory dies, and/or I/O dies) and package components (e.g., VRMs 148 and connectors 158). The package structure 10 may be referred to as a system-on-panel (SOP) device. Turning to FIG. 10A, a top-down view of the package structure 10 of FIG. 9 is shown according to an example embodiment. The package structure 10 may comprise the first region 162 in which the integrated circuit dies 50 and the package components (e.g., the VRMs 148 and the connectors 158) of the package structure 10 are disposed. In an embodiment, the first region 162 may be a central region of the package structure 10. In an embodiment, the package structure 10 may have a rectangular shape when seen in a top-down view, wherein the package structure 10 has four straight outer edges (e.g., first parallel edges oriented in the first direction (e.g., the x-direction), and second parallel edges oriented in the second direction (e.g., the y-direction that is perpendicular to the first direction)). In an embodiment, each of the first parallel edges may have the width W1 that is greater than 252 mm, and each of the second parallel edges may have the width W2 that is greater than 252 mm. In an embodiment, when seen in a top-down view, a top surface of the redistribution structure 112 may have a surface area that is greater than 63,504 mm². In an embodiment, the first region 162 may have a width W3 in the first direction (e.g., the x-direction), wherein the width W3 is a distance in the first direction (e.g., the x-direction) between a first outer sidewall of a first outermost one of the package components (e.g., a first outermost one of the VRMs 148 or the connectors 158) and a second outer sidewall of a second outermost one of the package components (e.g., a second outermost one of the VRMs 148 or the connectors 158). In an embodiment, the first region 162 may have a width W4 in the second direction (e.g., the y-direction), wherein the width W4 is a distance in the second direction (e.g., the y-direction) between a third outer sidewall of a third outermost one of the package components (e.g., a third outermost one of the VRMs 148 or the connectors 158) and a fourth outer sidewall of a fourth outermost one of the package components (e.g., a fourth outermost one of the VRMs 148 or the connectors 158). In an embodiment, each of the width W1, the width W2, the width W3 and the width W4 may be greater than 212 mm. In an embodiment, when seen in a top-down view, a top surface of the redistribution structure 112 that is disposed in the first region 162 may have a surface area that is greater than 44,944 mm². In an embodiment, the width W1 may be up to 510 mm, and the width W2 may be up to 515 mm. In an embodiment, the width W2 may be up to 510 mm, and the width W1 may be up to 515 mm.

Advantages can be achieved by forming the package structure 10 having a rectangular shape when seen in a top-down view, wherein the rectangular shape of the package structure 10 has four straight outer edges (e.g., first parallel edges of the redistribution structure 112 oriented in the first direction (e.g., the x-direction), and second parallel edges of the redistribution structure 112 oriented in the second direction (e.g., the y-direction that is perpendicular to the first direction)). In an embodiment, each of the first parallel edges may have the width W1 that is greater than 252 mm, and each of the second parallel edges may have the width W2 that is greater than 252 mm. In addition, in a top-down view, the package structure 10 may comprise the first region 162 in which the integrated circuit dies 50 and the package components (e.g., the VRMs 148 and the connectors 158) of the package structure 10 are disposed. The first region 162 may have the width W3 in the first direction (e.g., the x-direction), wherein the width W3 is a distance in the first direction (e.g., the x-direction) between a first outer sidewall of a first outermost one of the package components (e.g., a first outermost one of the VRMs 148 or the connectors 158) and a second outer sidewall of a second outermost one of the package components (e.g., a second outermost one of the VRMs 148 or the connectors 158). In an embodiment, the first region 162 may have the width W4 in the second direction (e.g., the y-direction), wherein the width W4 is a distance in the second direction (e.g., the y-direction) between a third outer sidewall of a third outermost one of the package components (e.g., a third outermost one of the VRMs 148 or the connectors 158) and a fourth outer sidewall of a fourth outermost one of the package components (e.g., a fourth outermost one of the VRMs 148 or the connectors 158). In an embodiment, each of the width W3 and the width W4 may be greater than 212 mm.

These advantages include the rectangular shape (e.g., the edges of the redistribution structure 112) of the package structure 10 allowing for a reduction in edge area waste compared to round wafer formats because of the elimination of curved edges. As a result, the rectangular shape of the redistribution structure 112 can be formed to have a top surface with a larger surface area. In addition, the larger dimensions (e.g., the width W1 and the width W2 of the edges of the redistribution structure 112 being greater than 252 mm, and the width W3 and the width W4 of the first region 162 being greater than 212 mm) of the package structure 10 allow for the integration of more integrated circuit dies 50 and package components (e.g., VRMs 148 and connectors 158) within the first region 162 of the package structure 10. This allows for increased design flexibility and reduces or eliminates the need for system-level interconnects between multiple smaller packages. As a result, device performance may be enhanced through reduced signal path lengths between components of the package structure 10, and improved power delivery can be achieved through the integrated VRMs 148 for high-performance computing applications.

In FIG. 10B, a top-down view of the package structure 10 is shown according to an example embodiment. The package structure 10 may comprise four first regions 162 arranged in a 2×2 array configuration, wherein each first region 162 functions as an independent system with its own integrated circuit dies 50 (which may include logic dies, memory dies, and/or I/O dies) and package components (e.g., VRMs 148 and connectors 158). As such, the package structure 10 may be referred to as a system-on-panel (SOP) device. In an embodiment, the package structure 10 may have a rectangular shape when seen in a top-down view, wherein the package structure 10 has four straight outer edges (e.g., first parallel edges oriented in the first direction (e.g., the x-direction), and second parallel edges oriented in the second direction (e.g., the y-direction that is perpendicular to the first direction)). In an embodiment, each of the first parallel edges may have the width W1 that is greater than 252 mm, and each of the second parallel edges may have the width W2 that is greater than 252 mm. In an embodiment, when seen in a top-down view, a top surface of the redistribution structure 112 may have a surface area that is greater than 63,504 mm². In an embodiment, the width W1 may be up to 510 mm, and the width W2 may be up to 515 mm. In an embodiment, the width W2 may be up to 510 mm, and the width W1 may be up to 515 mm.

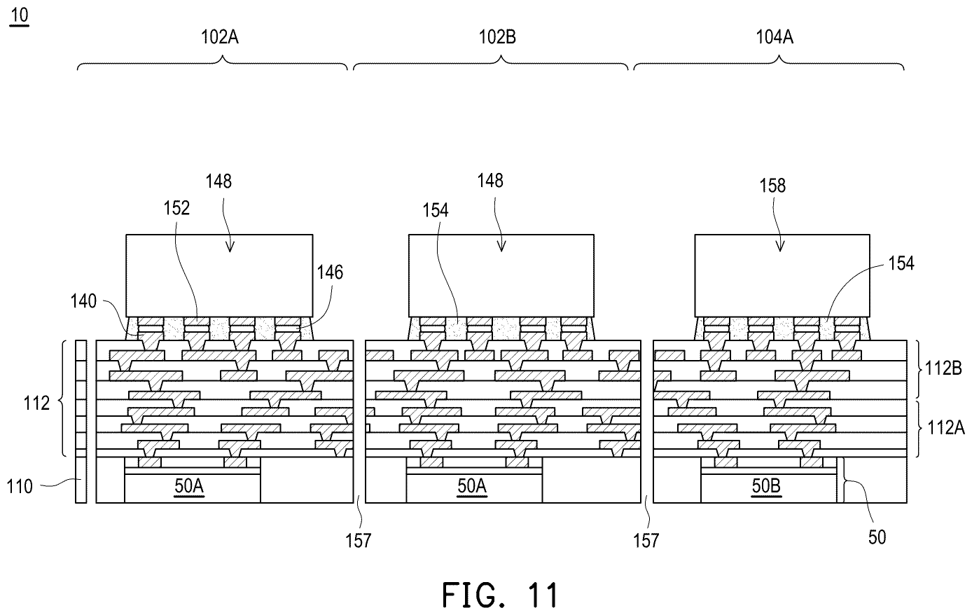

FIGS. 11 through 13 illustrate the integration and assembly of the package structure 10 with various assembly components to form a system 16, in accordance with some embodiments. The system 16 may be configured to support and enable operation of the package structure 10 in, for example, a high-performance computing environment, or the like. For example, the system 16 may provide mechanical support, thermal management, and electrical connections to allow the package structure 10 to function as an integrated computing system.

FIG. 11 illustrate the package structure 10 in accordance with some other embodiments. Unless specified otherwise, like reference numerals in this embodiment (and subsequently discussed embodiments) represent like components in the embodiment shown in FIGS. 1 through 10A formed by like processes. Accordingly, the process steps and applicable materials may not be repeated herein. The package structure 10 shown in the embodiment of FIG. 9 may be different from the package structure 10 shown in the embodiment of FIG. 11 in that in the package structure 10 shown in the embodiment of FIG. 11, screw holes 157 may be formed that extend through the redistribution structure 112 in different positions than the screw holes 141 that were shown in the FIG. 9. For example, the screw holes 157 may be disposed between adjacent package components (e.g., VRMs 148 and connectors 158) of the package structure 10. In addition, the screw holes 157 may be disposed between adjacent integrated circuit dies 50 of the package structure 10. The screw holes 157 may be formed using similar processes as those that were used to form the screw holes 141 that were described previously in FIG. 6. In addition, in the package structure 10 of the embodiment shown in FIG. 11, the underfill 154 does not overlap the portion of the redistribution structure 112 that is disposed between the VRMs 148.

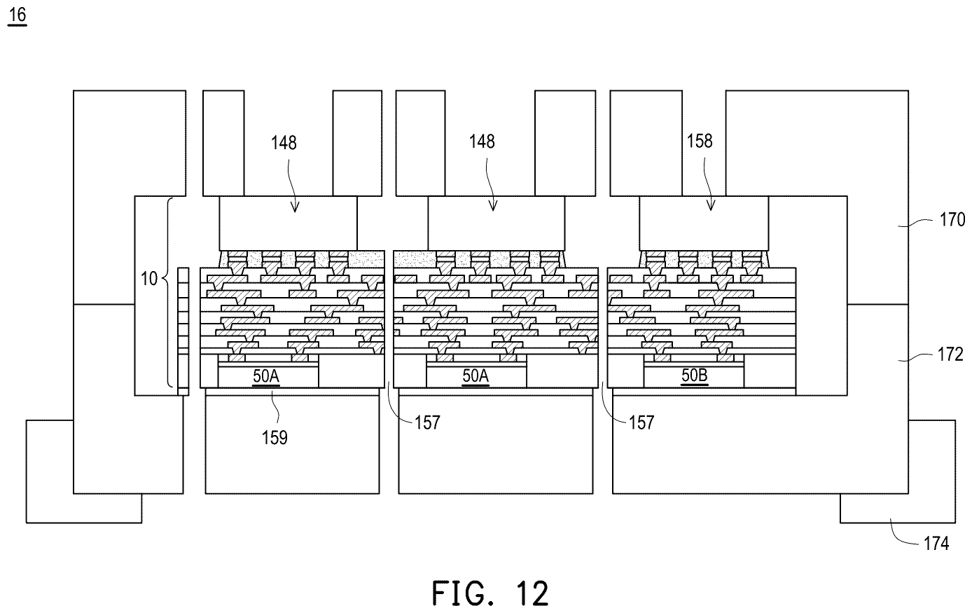

In FIG. 12, the package structure 10 may be positioned in a space between a cold plate 172 and an Input/Output (IO) frame 170. During the positioning, a support fixture 174 may be used to hold and support the package structure 10, the cold plate 172, and the IO frame 170. The support fixture 174 may ensure accurate alignment of the IO frame 170, package structure 10, and cold plate 172 relative to each other before final assembly of the system 16. For example, the cold plate 172 may first be positioned on the support fixture 174, such that the support fixture 174 supports the cold plate 172. The cold plate 172 may be a thermal management structure (also referred to as thermal module) that comprises a thermally conductive material (e.g., copper, aluminum, or the like) to dissipate heat from the package structure 10 during operation of the system 16. The cold plate 172 may comprise a bottom portion, on which the package structure 10 is disposed and supported. In an embodiment, before placing the package structure 10 on the bottom portion of the cold plate 172, a thermal interface material (TIM) 159 may be dispensed on the back side of the package structure 10, to physically and thermally couple the cold plate 172 to the integrated circuit dies 50 and the encapsulant 110. The TIM 159 may be a film comprising indium, a thermal grease, a thermal sheet, a phase change material, the like, or a combination thereof. The cold plate 172 may also comprise top portions that extend upwards from edges of the bottom portion of the cold plate 172. In an embodiment, the top portions of the cold plate 172 surround a bottom portion of the package structure 10, such that the package structure is disposed between inner sidewalls of the top portions of the cold plate 172.

The IO frame 170 is then positioned over the package structure 10 and the cold plate 172. The IO frame 170 may be a structural support component that comprises a rigid material (e.g., metal, reinforced polymer, or the like) to provide mechanical support for the package structure 10 during operation of the system 16. The IO frame 170 may comprise a top portion having openings arranged in a predetermined pattern for accessing the VRMs 148 and the connectors 158 of the package structure 10. The IO frame 170 may also comprise bottom portions that extend downwards from edges of the top portion of the IO frame 170. In an embodiment, the bottom portions of the IO frame 170 may surround a top portion of the package structure 10, such that the package structure 10 is disposed between inner sidewalls of the bottom portions of the IO frame 170. In an embodiment, the bottom portions of the IO frame 170 are aligned with and in contact with the top portions of the cold plate 172, such that the space between the cold plate 172 and the IO frame 170 is formed. In an embodiment, screw holes may extend through the top portion of the IO frame 170 and the bottom portion of the cold plate 172, wherein the screw holes of the top portion of the IO frame 170 and the bottom portion of the cold plate 172 are aligned with the screw holes 157 in the package structure 10. In an embodiment, the top portion of the IO frame 170 may be in contact with top surfaces of the package structure 10 (e.g., top surfaces of the VRMs 148 and/or the connectors 158).

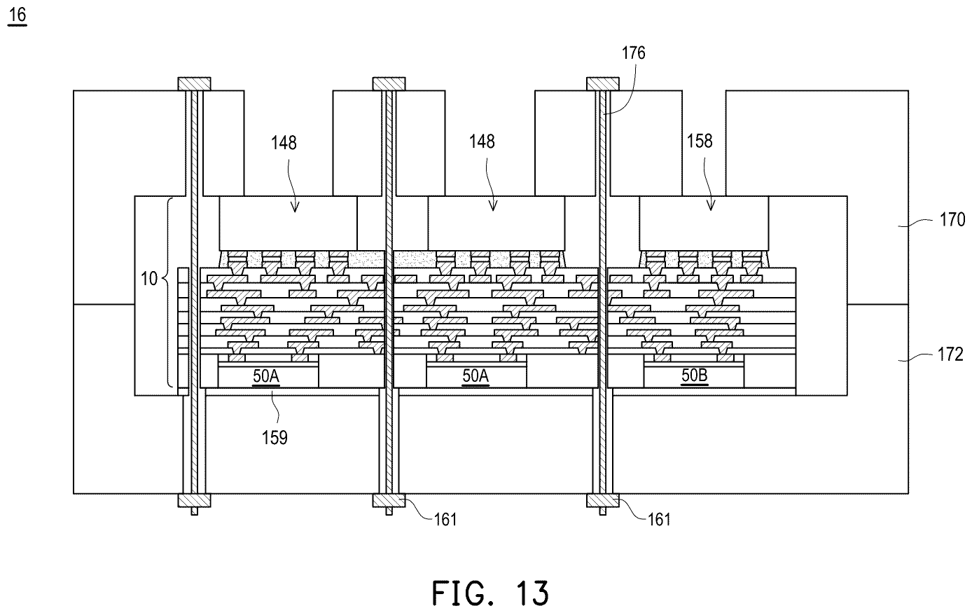

In FIG. 13, the package structure 10 may be fastened between the IO frame 170 and the cold plate 172 using screws 176 to form the system 16. The screws may be inserted through the screw holes in the top portion of the IO frame 170, through the screw holes 157 of the package structure 10, and through corresponding screw holes in the bottom portion of the cold plate 172. Fasteners 161 may be threaded onto the screws 176 and tightened to clamp the package structure 10 between the IO frame 170 and cold plate 172. The fasteners 161 may be, e.g., nuts that thread to the screws 176 at opposite ends of each screw 176. During the fastening process, the fasteners 161 may be tightened to apply enough mechanical force to secure the package structure 10 between the IO frame 170 and the cold plate 172, ensuring proper mechanical support and thermal contact between the cold plate 172 and the package structure 10. After the package structure 10 is fastened between the IO frame 170 and the cold plate 172 to form the system 16, the system 16 may be removed from the support fixture 174. In other embodiments, the system 16 may also include additional thermal management and control components disposed between the package structure 10 and the IO frame 170. For example, an additional cold plate may be positioned over the package structure 10, and a control board may be positioned over the additional cold plate. The IO frame 170 may then be positioned over the control board. The control board may, for example, manage power delivery and signal routing for the system 16.

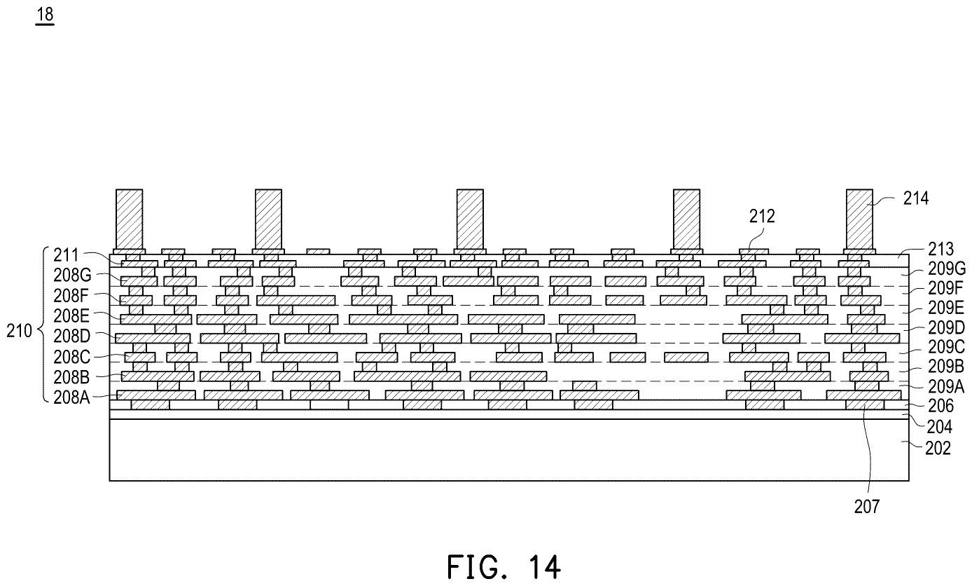

FIGS. 14-19 illustrate cross-sectional views of intermediate steps during a process for forming a package structure 18, in accordance with some embodiments. The package structure 18 is an alternative embodiment in which like reference numerals represent like components in the embodiment shown in FIGS. 1 through 13, unless specified otherwise. Accordingly, the process steps and applicable materials may not be repeated herein.

In FIG. 14, a carrier substrate 202 is provided, and an adhesive layer 204 is formed on the carrier substrate 202, in accordance with some embodiments. The carrier substrate 202 may be a glass carrier substrate, a ceramic carrier substrate, or the like. The carrier substrate 202 may have a rectangular shape that includes four straight edges (e.g., first parallel edges oriented in a first direction, and second parallel edges oriented in a second direction that is perpendicular to the first direction) when seen in a top-down view, wherein a length of each straight edge may be greater than 252 mm. The adhesive layer 204 may be removed along with the carrier substrate 202 from the overlying structures that will be formed in subsequent steps. In some embodiments, the adhesive layer 204 is any suitable adhesive, epoxy, die attach film (DAF), or the like, and is applied over the surface of the carrier substrate 202.

A back-side redistribution structure 210 may then be formed over the carrier substrate 202. To form the back-side redistribution structure 210, conductive pads 207 (which may also be referred to as a metallization pattern) may first be formed over the carrier substrate 202 and the adhesive layer 204. To form the conductive pads 207, a seed layer is formed over the adhesive layer 204. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by, for example, a slit coating process using the slit coating apparatus 12 that was described previously in FIGS. 4A and 4B, or the like. The photoresist may be exposed to a laser beam or light for patterning, using for example, a LDI process using the LDI apparatus, or using the stepper that was described previously in FIG. 4A. The pattern of the photoresist corresponds to the conductive pads 207. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the conductive pads 207. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

After the formation of the conductive pads 207, a dielectric layer 206 is deposited over the conductive pads 207 and the adhesive layer 204, such that the conductive pads 207 are embedded in the dielectric layer 206. In some embodiments, the dielectric layer 206 is formed of a photo-sensitive material such as polyimide, PBO, BCB, or the like. In an embodiment, the dielectric layer 206 may be formed by, for example, using a slit coating process using the slit coating apparatus 12 that was described previously in FIGS. 4A and 4B, or the like. After the formation of the dielectric layer 206, a planarization step, such as a chemical mechanical polish (CMP), may be performed to remove excess portions of the dielectric layer 206, and to expose top surfaces of the conductive pads 207. Accordingly, top surfaces of the dielectric layer 206 are level with top surfaces of the conductive pads 207.

Referring further to FIG. 14, the remainder of the back-side redistribution structure 210 is formed over the dielectric 206 and the conductive pads 207, in accordance with some embodiments. The remainder of the back-side redistribution structure 210 may comprise insulating layers 209A-G (e.g., insulating layer 209A, insulating layer 209B, insulating layer 209C, insulating layer 209D, insulating layer 209E, insulating layer 209F, and insulating layer 209G), and metallization patterns 208A-G (e.g., metallization pattern 208A, metallization pattern 208B, metallization pattern 208C, metallization pattern 208D, metallization pattern 208E, metallization pattern 208F, and metallization pattern 208G). In some embodiments, the back-side redistribution structure 210 may have any number of insulating layers or metallization patterns. The metallization patterns may also be referred to as redistribution layers or redistribution lines.

As an example to form the remainder of the back-side redistribution structure 210, the metallization pattern 208A may then be formed to provide additional routing. In an embodiment, the metallization pattern 208A may be formed using materials and processes similar to the conductive pads 207. For example, a seed layer (not shown) may be formed over the conductive pads 207 and the dielectric layer 206, a photoresist formed (e.g., by performing a slit coating process using the slit coating apparatus 12 that was described previously in FIGS. 4A and 4B), and patterned (using for example, a LDI process using the LDI apparatus, or using the stepper that was described previously in FIG. 4A) on top of the seed layer in a desired pattern for the metallization pattern 208A, and conductive material (e.g., copper, titanium, or the like) may then be formed in the patterned openings of the photoresist using e.g., a plating process. The photoresist may then be removed and the seed layer etched, forming the metallization pattern 208A. In this manner, the metallization pattern 208A may form electrical connections to the conductive pads 207.

The insulating layer 209A is then formed on the metallization pattern 208A and dielectric layer 206. In some embodiments, the insulating layer 209A is formed of Ajinomoto build-up film (ABF), or the like, which may be formed by lamination, or the like. The insulating layer 209A may then be patterned. The patterning forms openings exposing portions of the metallization pattern 208A. The patterning may be performed by etching using, for example, an anisotropic etch process, wherein a photoresist is used as an etch mask. The photoresist may be formed, for example, by performing a slit coating process using the slit coating apparatus 12 that was described previously in FIGS. 4A and 4B, or the like. The photoresist may then be patterned using, for example, by performing a LDI process using the LDI apparatus, or by using the stepper that was described previously in FIG. 4A.

The metallization pattern 208B is then formed. The metallization pattern 208B has line portions on and extending along the major surface of the insulating layer 209A, and has via portions extending through the openings in the insulating layer 209A to physically and electrically couple the metallization pattern 208A. As an example to form the metallization pattern 208B, a seed layer is formed over the insulating layer 209A and in the openings extending through the insulating layer 209A. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed, for example, by performing a slit coating process using the slit coating apparatus 12 that was described previously in FIGS. 4A and 4B, or the like. The photoresist may then be patterned using, for example, by performing a LDI process using the LDI apparatus, or by using the stepper that was described previously in FIG. 4A. The pattern of the photoresist corresponds to the metallization pattern 208B. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 208B. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

Additional insulating layers 209B-G and additional metallization patterns 208C-G may then be formed over the metallization pattern 208B and insulating layer 209A to provide additional routing. The insulating layers 209B-G and metallization patterns 208C-G may be formed in alternating layers, and may be formed using processes and materials similar to those used for the insulating layer 209A and the metallization pattern 208B, respectively. The steps described above may be repeated to form a suitable number and configuration of insulation layers and redistribution layers. In other embodiments, the insulating layers 209A-G and metallization patterns 208B-G may be formed using different processes than described herein.

After the formation of the insulating layers 209B-G and the metallization patterns 208C-G, a metallization pattern 211 is then formed. The metallization pattern 211 has line portions on and extending along the major surface of the insulating layer 209G, and has via portions extending through the openings in the insulating layer 209G to physically and electrically couple the metallization pattern 208G. The metallization pattern 211 may be formed using similar materials and processes as were used for the formation of the metallization pattern 208B. After the formation of the metallization pattern 211, a dielectric layer 213 is deposited over the metallization pattern 211 and the insulating layer 209G. In some embodiments, the dielectric layer 213 is formed of a photo-sensitive material such as polyimide, PBO, BCB, or the like. In an embodiment, the dielectric layer 206 may be formed by, for example, by performing a slit coating process using the slit coating apparatus 12 that was described previously in FIGS. 4A and 4B, or the like.

After the formation of the dielectric layer 213, the dielectric layer 213 may then be patterned. The patterning forms openings exposing portions of the metallization pattern 211. In an embodiment, when the dielectric layer 213 is a photo-sensitive material, the patterning may include performing a LDI process using the LDI apparatus, or using the stepper that was described previously in FIG. 4A. In other embodiments, the patterning may be performed by etching using, for example, an anisotropic etch process, wherein a photoresist is used as an etch mask. The photoresist may be formed by, for example, performing a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. After exposure by either the LDI process or by using the stepper, the photoresist is developed to form the patterned photoresist, which is then used as a mask during the anisotropic etching of the dielectric layer 213.

The metallization pattern 212 is then formed. The metallization pattern 212 has line portions (also referred to as conductive lines or traces) on and extending along the major surface of the dielectric layer 213, and has via portions (also referred to as conductive vias) extending through the dielectric layer 213 to physically and electrically couple to the metallization pattern 211. The metallization pattern 212 may also include conductive pads that extend along the major surface of the dielectric layer 213. As an example to form the metallization pattern 212, a seed layer is formed over the dielectric layer 213 and in the openings extending through the dielectric layer 213. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by, for example, performing a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. The pattern of the photoresist corresponds to the metallization pattern 212. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 212. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

Referring further to FIG. 14, after the formation of the back-side redistribution structure 210, conductive vias 214 (which may also be referred to subsequently as through-vias) are formed over and electrically connected to the back-side redistribution structure 210. As an example to form the conductive vias 214, a photoresist is formed over the back-side redistribution structure 210 by, for example, performing a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. The pattern of the photoresist corresponds to the conductive vias 214. The patterning forms openings through the photoresist to expose conductive pads of the metallization pattern 212. A conductive material is formed in the openings of the photoresist and on the exposed portions (e.g., the conductive pads) of the metallization pattern. The conductive material may be formed by plating, such as electroplating or electroless plating, or the like. The conductive material may comprise a metal, like copper, titanium, tungsten, aluminum, or the like. The photoresist may then be removed by an acceptable ashing or stripping process, such as using an oxygen plasma or the like. Once the photoresist is removed, the remaining portions of the conductive material form the conductive vias 214.

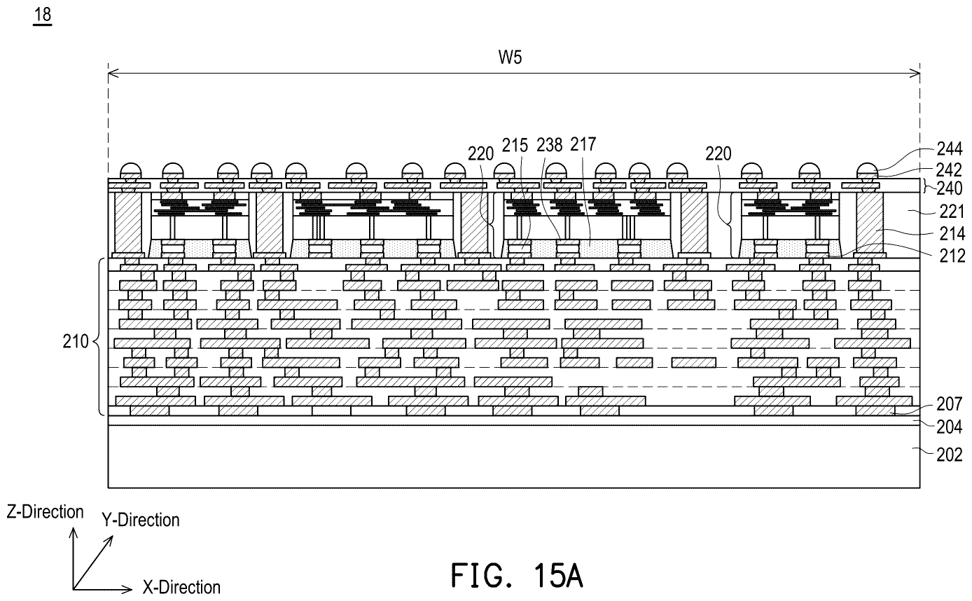

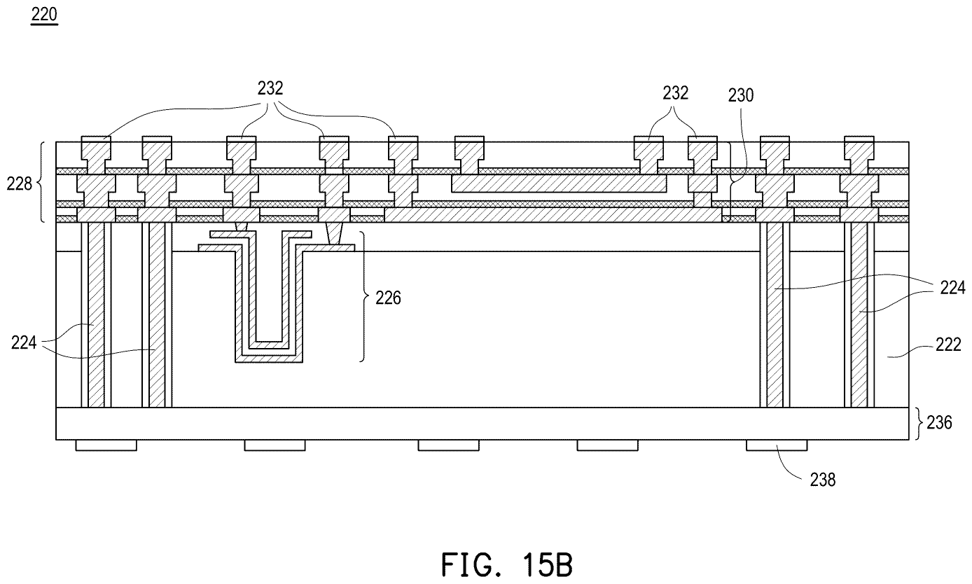

FIG. 15A further illustrates the bonding of a plurality of dies 220 to the back-side redistribution structure 210. The bonded dies 220 may include one or more active dies, integrated voltage regulator (IVR) dies and/or discrete dies. As an example, the plurality of dies 220 may comprise one or more active dies (e.g., integrated circuit dies 50 that were described previously in FIG. 1) that may include active electronic components such as transistors for performing processing or memory functions. In an embodiment, the plurality of dies 220 may comprise one or more discrete dies that may be, for example, passive device dies, interconnect dies, or the like. For example, the one or more discrete dies may include an Independent Passive Device (IPD) die including a capacitor therein, an IPD die including a resistor therein, an interconnect die for bridging two device dies, and/or the like. In an embodiment, the plurality of dies 220 may comprise one or more IVR dies that include voltage regulators for regulating voltage supplies for overlying dies. In an embodiment, the one or more IVR dies may comprise active devices such as transistors, or the like. In an embodiment, the one or more IVR dies may comprise passive devices such as capacitors, transformers, inductors, resistors, and the like. In other embodiments, the plurality of dies 220 may comprise one or more embedded Die-to-Die Connection (eDTC) dies that manage high-speed communication between other dies.

FIG. 15B illustrates an example die 220 that may be a discrete die, in accordance with some embodiments. It is appreciated that die 220 represents some of the possible structures of discrete dies, and may include one or more of features such as through-vias, interconnect paths, capacitors, and the like. Die 220 may include substrate 222, which may be a semiconductor substrate such as a silicon substrate. Substrate 222 may also be a dielectric substrate, which is formed of a dielectric material such as silicon oxide, silicon nitride, or the like. In accordance with an embodiment, through-vias 224 are formed to extend into substrate 222.

In accordance with some embodiments, die 220 is free from active devices such as transistors and diodes therein. Die 220 may or may not include passive devices such as capacitors, transformers, inductors, resistors, and the like. In accordance with alternative embodiments of the present disclosure, die 220 may include passive devices. For example, die 220 may be an IPD die including capacitor 226 (which may be a deep-trench capacitor) formed in die 220. Die 220 may also be an IPD die including a resistor therein.

Die 220 may act as a bridge die (sometimes referred to as a local silicon interconnect (LSI)), and may include interconnect structure 228 over substrate 222. Interconnect structure 228 further includes dielectric layers and metal lines and vias in the dielectric layers. The dielectric layers may include Inter-Metal Dielectric (IMD) layers. In accordance with some embodiments, some of the dielectric layers are formed of low-k dielectric materials having dielectric constant values (k-value) lower than 3.8, and the k-values may be lower than about 3.0 or about 2.5. The low-k dielectric layers may be formed of a carbon-containing low-k dielectric material, Hydrogen SilsesQuioxane (HSQ), MethylSilsesQuioxane (MSQ), or the like. The formation of the metal lines and vias within the interconnect structure 228 may include single damascene and dual damascene processes. Bond structures 232 such as metal pillars or metal pads are formed at the surface of die 220. Die 220 may include bridges 230, which include metal lines and vias. Each of the bridges 230 is connected to two bond structures 232, so that the bridges 230 may be used to electrically interconnect two or more package components (such as device dies) in subsequent processes. Die 220 may further include an interconnect structure 236 formed on a bottom surface of the substrate 222, wherein the interconnect structure 236 may include dielectric layers and metal lines and vias similar to those of the interconnect structure 228. Bond structures 238, such as metal pillars or metal pads, may be formed on the bottom surface of the interconnect structure 236 to provide electrical connections to the interconnect structure 228 by way of the through-vias 224.

Referring back to FIG. 15A, in accordance with some embodiments, the bonding of the plurality of dies 220 to the back-side redistribution structure 210 may be performed through solder bonding or metal-to-metal direct bonding. For example, the bonding may be performed through solder regions 215. In an embodiment, a single die 220 may be bonded between each pair of conductive vias 214. In an embodiment, any number of dies 220 may be bonded between each pair of conductive vias 214. Although FIG. 15A shows four dies 220 that are bonded to the back-side redistribution structure 210, it should be appreciated that any number of dies 220 may be bonded to the back-side redistribution structure 210. After the bonding, underfill 217 may be dispensed into a gap between each die 220 and the back-side redistribution structure 210. In accordance with some embodiments, underfill 217 may include a base material, which may include a polymer, a resin, an epoxy, and/or the like, and filler particles in the base material. The filler particles may be dielectric particles of silica, alumina, boron nitride, or the like, and may have spherical shapes.

After the formation of the underfill 217, an encapsulation process may be performed to surround the dies 220 and the conductive vias 214 with an encapsulant 221. The encapsulant 221 may comprise a granulated molding compound that includes, for example, epoxy resin particles mixed with silica filler particles. The encapsulant 221 may be applied by compression molding, transfer molding, or the like. In an embodiment, during the encapsulation process, the encapsulant 221 may be heated to a temperature where the epoxy resin particles melt and flow, after which the encapsulant is applied on and around the dies 220 and the conductive vias 214, and over the back-side redistribution structure 210. As a result, the encapsulant 221 surrounds the dies 220 and the conductive vias 214. Subsequently, the encapsulant 221 may be cured (e.g., by exposing the encapsulant 221 to elevated temperatures). In some embodiments, the encapsulant 221 is formed over the back-side redistribution structure 210 such that the dies 220 and the conductive vias 214 are buried or covered, and a planarization process may then be performed on the encapsulant 221 to expose a metallization pattern or bond pads (e.g., the bond structures 232) of the dies 220. Topmost surfaces of the encapsulant 221, the dies 220, and the conductive vias 214 may be coplanar after the planarization process. The planarization process may include, for example, a chemical-mechanical polish (CMP) process or a grinding process. After the planarization process is performed, in an embodiment, a width W5 of the package structure 18 in a first direction (e.g., the x-direction) may be greater than 252 mm. In an embodiment, a width W6 of the package structure 18 in a second direction (e.g., the y-direction) that is perpendicular to the first direction may be greater than 252 mm. In an embodiment, after the planarization process is performed, the package structure 18 may have a rectangular shape when seen in a top-down view, wherein the rectangular shape includes four straight edges (e.g., first parallel edges oriented in the first direction (e.g., the x-direction) having the width W5, and second parallel edges oriented in the second direction (e.g., the y-direction that is perpendicular to the first direction) having the width W6), wherein each of the widths W5 and the widths W6 of the straight edges may be greater than 252 mm. In an embodiment, after the planarization process is performed, a top surface (e.g., including the topmost surfaces of the encapsulant 221, the dies 220, and the conductive vias 214) of the package structure 18 may have a surface area that is greater than 63,504 mm².

Referring further to FIG. 15A, a front-side redistribution structure 240 is formed over the encapsulant 221, the dies 220, and the conductive vias 214. The front-side redistribution structure 240 may include a dielectric layer and a metallization pattern within the dielectric layer. The metallization pattern may also be referred to as redistribution layer or redistribution line. More dielectric layers and metallization patterns may be formed in the front-side redistribution structure 240 than are shown in FIG. 15A. If more dielectric layers and metallization patterns are to be formed, steps and processes discussed below may be repeated.

To form the front-side redistribution structure 240, the dielectric layer is deposited on the encapsulant 221, the dies 220, and the conductive vias 214. In some embodiments, the dielectric layer is formed of a photo-sensitive material such as polyimide, PBO, BCB, or the like. In an embodiment, the dielectric layer may be formed by, for example, by performing a slit coating process using the slit coating apparatus 12 that was described previously in FIGS. 4A and 4B, or the like.

After the formation of the dielectric layer, the dielectric layer may then be patterned. The patterning forms openings exposing top surfaces of the dies 220 (e.g., a metallization pattern or bond pads (e.g., the bond structures 232) of the dies 220) and the conductive vias 214. In an embodiment, when the dielectric layer is a photo-sensitive material, the patterning may include performing a LDI process using the LDI apparatus, or using the stepper that was described previously in FIG. 4A. In other embodiments, the patterning may be performed by etching using, for example, an anisotropic etch process, wherein a photoresist is used as an etch mask. The photoresist may be formed by, for example, a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. After exposure by either the LDI process or by using the stepper, the photoresist is developed to form the patterned photoresist, which is then used as a mask during the anisotropic etching of the dielectric layer.

The metallization pattern is then formed. The metallization pattern has line portions (also referred to as conductive lines or traces) on and extending along the major surface of the dielectric layer, and has via portions (also referred to as conductive vias) extending through the dielectric layer to physically and electrically couple to the metallization pattern or bond pads (e.g., the bond structures 232) of the dies 220, and the conductive vias 214. As an example to form the metallization pattern, a seed layer is formed over the dielectric layer and in the openings extending through the dielectric layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by, for example, performing a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. The pattern of the photoresist corresponds to the metallization pattern. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

After the formation of the front-side redistribution structure 240, Under-Bump Metallurgies (UBMs) 242 and conductive connectors 244 may be formed over and electrically connected to the front-side redistribution structure 240. The UBMs 242 may comprise a plurality of layers of conductive materials, such as a layer of titanium, a layer of copper, and/or a layer of nickel. However, other arrangements of materials and layers may be used, such as an arrangement of chrome/chrome-copper alloy/copper/gold, an arrangement of titanium/titanium tungsten/copper, or an arrangement of copper/nickel/gold, that are suitable for the formation of the UBMs 242. Any suitable materials or layers of material that may be used for the UBMs 242 are fully intended to be included within the scope of the current application. The UBMs 242 may be created by forming each layer of the UBMs 242 over the front-side redistribution structure 240. The forming of each layer may be performed using a plating process (e.g., electroplating or electroless plating), sputtering, evaporation, PECVD, or the like. Once the layers of the UBMs 242 have been formed, portions of the layers may then be removed through a suitable photolithographic masking and etching process.

After the formation of the UBMs 242, the conductive connectors 244 are then formed over the front-side redistribution structure 240. The conductive connectors 244 may be formed on the UBMs 242. The conductive connectors 244 may comprise micro bumps, ball grid array (BGA) connectors, solder balls, metal pillars, controlled collapse chip connection (C4) bumps, contact bumps, electroless nickel-electroless palladium-immersion gold technique (ENEPIG) formed bumps, or the like. The conductive connectors 244 may comprise a conductive material such as solder, copper, aluminum, gold, nickel, silver, palladium, tin, the like, or a combination thereof. In some embodiments, the conductive connectors 244 are formed by initially forming a layer of solder through evaporation, electroplating, printing, solder transfer, ball placement, or the like. Once a layer of solder has been formed on the structure, a reflow may be performed in order to shape the material into the desired bump shapes. In some embodiments, the conductive connectors 244 comprise metal pillars (such as a copper pillar) formed by a sputtering, printing, electro plating, electroless plating, CVD, or the like.

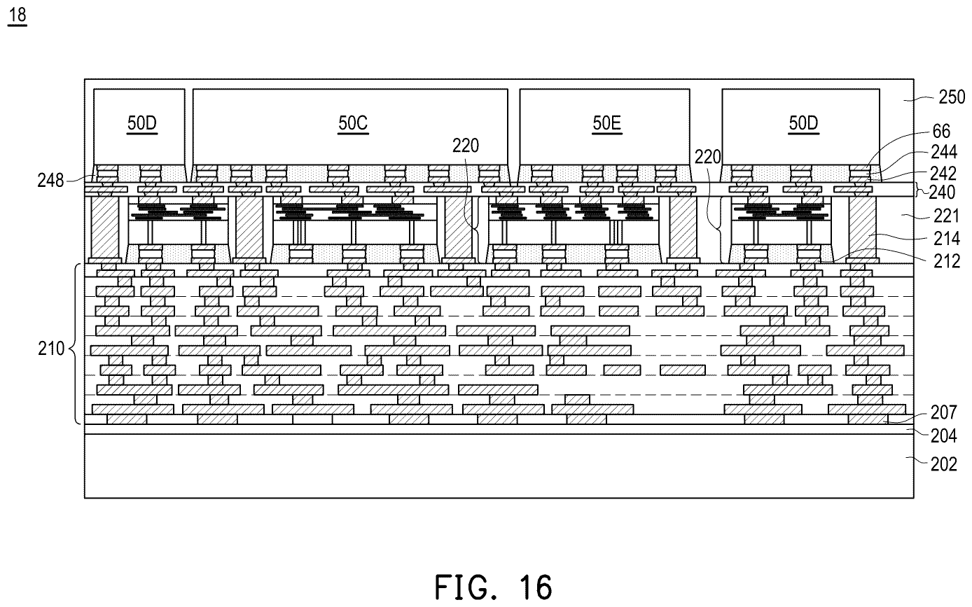

In FIG. 16, a desired type and quantity of integrated circuit dies 50 (described previously in FIG. 1) are coupled to the front-side redistribution structure 240. For example, the integrated circuit dies 50 may be placed on the conductive connectors 244 on the front-side redistribution structure 240, making electrical connection between the integrated circuit dies 50 and the front-side redistribution structure 240. The integrated circuit dies 50 may be placed on the conductive connectors 244 using a placement process such as a pick-and-place process, or the like. The integrated circuit dies 50 may be placed such that the die connectors 66 of the integrated circuit dies 50 are aligned with the conductive connectors 244 on the front-side redistribution structure 240. Once in physical contact, a reflow process may be utilized to bond the conductive connectors 244 to the integrated circuit dies 50. An underfill 248 may then be formed between each integrated circuit die 50 and the front-side redistribution structure 240, surrounding the conductive connectors 244. In an embodiment, the integrated circuit dies 50 may include one or more of a first type of integrated circuit die, such as a SoC die 50C, one or more of a second type of integrated circuit die, such as an I/O interface die 50D, and one or more of a third type of integrated circuit die, such as a high bandwidth memory (HBM) die 50E. It should be appreciated that any number and any type of the integrated circuit dies 50 may be coupled to the front-side redistribution structure 240.

After the formation of the underfill 248, an encapsulation process may be performed to surround the integrated circuit dies 50 with an encapsulant 250. The encapsulant 250 may be formed using similar processes and similar materials as were used to form the encapsulant 221 that was described previously in FIG. 15A. In some embodiments, the encapsulant 250 is formed over the front-side redistribution structure 240 such that the integrated circuit dies 50 are buried or covered, and a planarization process may then be performed on the encapsulant 250 to reduce a thickness of the encapsulant 250. After the planarization process, topmost surfaces of the encapsulant 250 may be above topmost surfaces of the integrated circuit dies 50. The planarization process may include, for example, a chemical-mechanical polish (CMP) process or a grinding process.

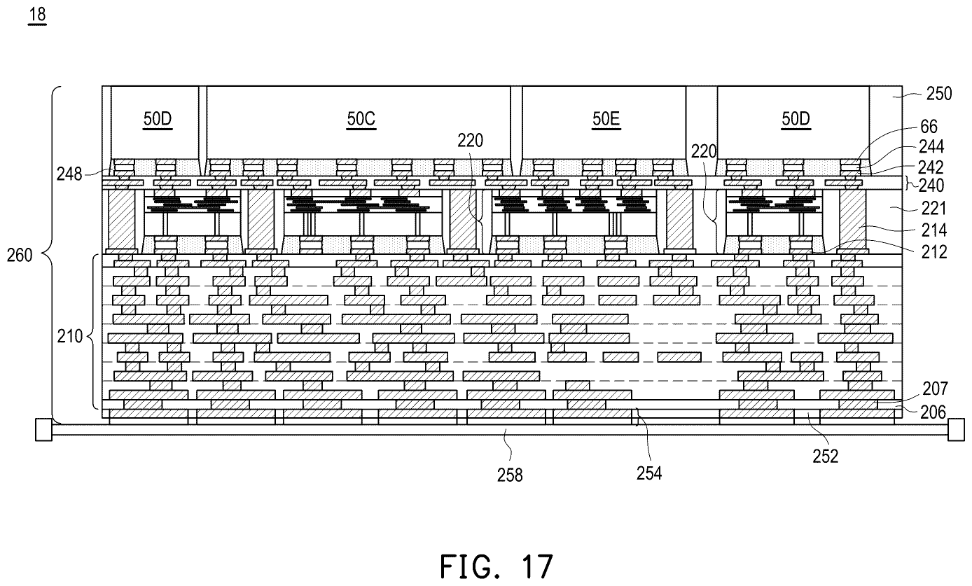

In FIG. 17, a carrier substrate debonding is performed to detach (or “debond”) the carrier substrate 202 from the package structure 18. In some embodiments, the debonding includes removing the carrier substrate 202 and adhesive layer 204 by, e.g., a grinding or planarization process, such as a CMP process. After removal, surfaces of the conductive pads 207 and the dielectric layer 206 may be exposed. A dielectric layer 252 may be deposited over the exposed surfaces of the conductive pads 207 and the dielectric layer 206. In some embodiments, the dielectric layer 252 is formed of a photo-sensitive material such as polyimide, PBO, BCB, or the like. In an embodiment, the dielectric layer 252 may be formed by, for example, by performing a slit coating process using the slit coating apparatus 12 that was described previously in FIGS. 4A and 4B, or the like.

After the formation of the dielectric layer 252, the dielectric layer 252 may then be patterned. The patterning forms openings exposing portions of the conductive pads 207. In an embodiment, when the dielectric layer 252 is a photo-sensitive material, the patterning may include performing a LDI process using the LDI apparatus, or using the stepper that was described previously in FIG. 4A. In other embodiments, the patterning may be performed by etching using, for example, an anisotropic etch process, wherein a photoresist is used as an etch mask. The photoresist may be formed by, for example, performing a slit coating process using the slit coating apparatus 12 that was described previously in FIGS. 4A and 4B, or the like. The photoresist may then be exposed to a laser beam or light for patterning, using for example, a LDI process using the LDI apparatus, or using the stepper that was described previously in FIG. 4A. After exposure by either the LDI process or by using the stepper, the photoresist is developed to form the patterned photoresist, which is then used as a mask during the anisotropic etching of the dielectric layer 252.

After patterning the dielectric layer 252, Under-Bump Metallurgies (UBMs) 254 may be formed over and electrically connected to the conductive pads 207. The UBMs 254 may comprise a plurality of layers of conductive materials, such as a layer of titanium, a layer of copper, and/or a layer of nickel. However, other arrangements of materials and layers may be used, such as an arrangement of chrome/chrome-copper alloy/copper/gold, an arrangement of titanium/titanium tungsten/copper, or an arrangement of copper/nickel/gold, that are suitable for the formation of the UBMs 254. Any suitable materials or layers of material that may be used for the UBMs 254 are fully intended to be included within the scope of the current application. The UBMs 254 may be created by forming each layer of the UBMs 254 over the dielectric layer 206 and the conductive pads 207. The forming of each layer may be performed using a plating process (e.g., electroplating or electroless plating), sputtering, evaporation, PECVD, or the like. Once the layers of the UBMs 254 have been formed, portions of the layers may then be removed through a suitable photolithographic masking and etching process. Once the UBMs 254 are formed, the structure (e.g., which may be referred to as a structure 260) may be placed on a tape 258. A planarization process may then be performed on the encapsulant 250 to expose topmost surfaces of the integrated circuit dies 50. After the planarization process, topmost surfaces of the encapsulant 250 may be co-planar with the topmost surfaces of the integrated circuit dies 50. The planarization process may include, for example, a chemical-mechanical polish (CMP) process or a grinding process.

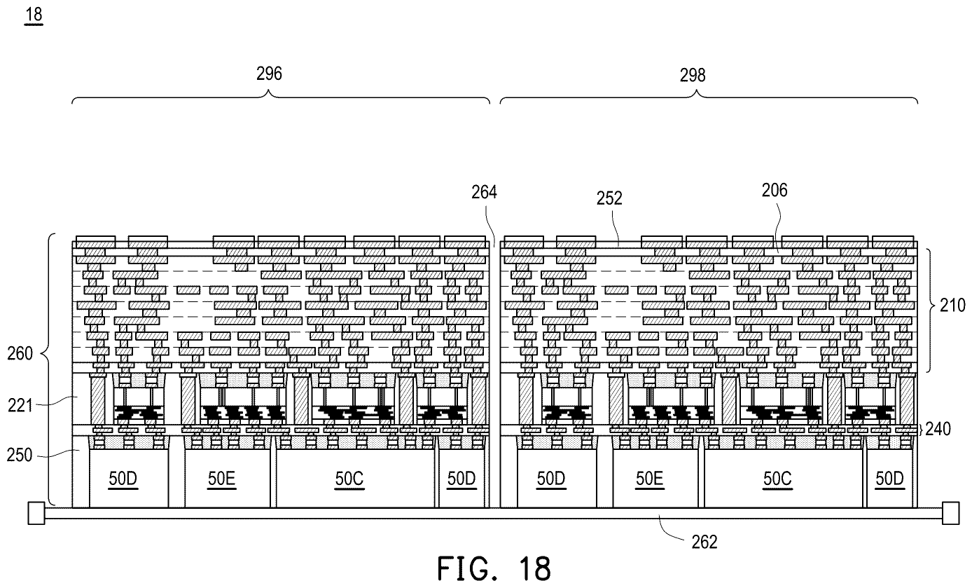

FIG. 18 illustrates the structure 260 of the package structure 18 in accordance with an example embodiment. Unless specified otherwise, like reference numerals in this embodiment (and subsequently discussed embodiments) represent like components in the embodiment shown in FIGS. 1 through 17 formed by like processes. Accordingly, the process steps and applicable materials may not be repeated herein. The structure 260 in FIG. 18 is shown to comprise a greater number of dies 220 and integrated circuit dies 50. In an embodiment, the structure 260 may comprise any number of dies 220 and integrated circuit dies 50. In FIG. 18, the structure 260 may be flipped over and placed on a tape 262. Screw holes 264 may then be formed through the structure 260. For example, the screw holes 264 may extend through the back-side redistribution structure 210, the dielectric layer 252, the dielectric layer 206, the encapsulant 221, the encapsulant 250, and the front-side redistribution structure 240. The screw holes 264 may be formed by a drilling process such as laser drilling, mechanical drilling, or the like. The screw holes 264 may be formed by drilling an outline for the screw holes 264 using a drilling process, and then removing the material separated by the outline, for example. In an embodiment, screws may be subsequently positioned to extend through the screw holes 264 in order to secure the package structure 18 to and/or between other structures. The structure 260 of the package structure 18 may include different package regions, such as one or more voltage regulation sites 298 and one or more connecting sites 296. Each of the voltage regulation sites 298 may have one or more first package components 284 subsequently coupled to the voltage regulation site 298. Each of the connecting sites 296 may have one or more second package components 282 subsequently coupled to the connecting site 296.

In an embodiment, the structure 260 may have a rectangular shape when seen in a top-down view, wherein the structure 260 has four straight outer edges (e.g., first parallel edges of the structure 260 oriented in the first direction (e.g., the x-direction), and second parallel edges of the structure 260 oriented in the second direction (e.g., the y-direction that is perpendicular to the first direction)). In an embodiment, each of the first parallel edges may have the width W5 that is greater than 252 mm, and each of the second parallel edges may have the width W6 that is greater than 252 mm. In an embodiment, when seen in a top-down view, a top surface of the structure 260 may have a surface area that is greater than 63,504 mm².

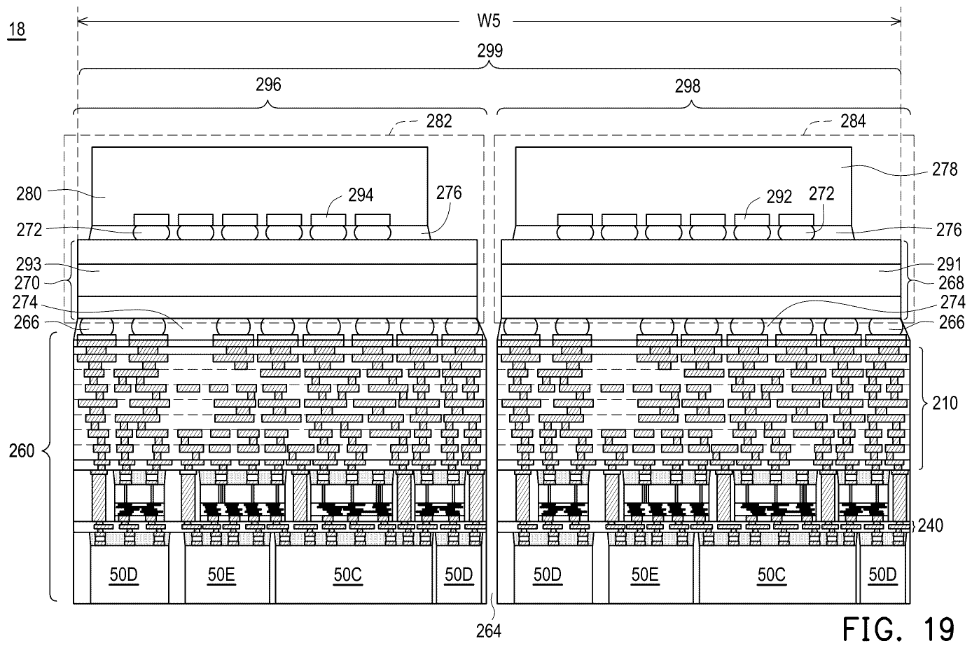

In FIG. 19, a first package component 284 is coupled to each of the voltage regulation sites 298, and a second package components 282 is coupled to each of the connecting sites 296. In an embodiment, any number of first package components 284 and second package components 282 may be coupled to each of the voltage regulation sites 298, and connecting sites 296, respectively. Each first package component 284 may comprise a VRM 278 that is coupled to a substrate 268 using conductive connectors 272. The VRM 278 may be a power management component that comprises active devices (e.g., power transistors, control ICs) and passive devices (e.g., inductors, capacitors, transformers) for converting and regulating voltage levels. The VRM 278 may include bond pads 292 on a bottom surface that are used for electrical connection to the substrate 268 through the conductive connectors 272. The VRM 278 may be configured to receive input power through the substrate 268 and provide regulated output voltages to the integrated circuit dies 50 of the structure 260 of the package structure 18. In operation, the VRM 278 manages power delivery by monitoring voltage levels, adjusting output voltages based on load requirements, and maintaining stable power supply to the integrated circuit dies 50.

The substrate 268 may include a substrate core 291 and first bond pads over the substrate core 291, and second bond pads below the substrate core 291. The substrate core 291 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 291 may be an SOI substrate. Generally, an SOI substrate includes a layer of a semiconductor material such as epitaxial silicon, germanium, silicon germanium, SOI, SGOI, or combinations thereof. The substrate core 291 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 291.

The substrate 268 may also include metallization layers and vias (not shown) disposed above the substrate core 291 and below the substrate core 291, with the first bond pads being physically and/or electrically coupled to the metallization layers and vias that are disposed above the substrate core 291, and the second bond pads being physically and/or electrically coupled to the metallization layers and vias that are disposed below the substrate core 291. The metallization layers may be formed over active and passive devices of the substrate 268 and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 291 is substantially free of active and passive devices. Conductive vias may extend through the substrate core 291 to provide electrical connections between the metallization layers and vias (not shown) disposed above the substrate core 291 and the metallization layers and vias (not shown) disposed below the substrate core 291. An underfill material 276 may be dispensed between the VRM 278 and the substrate 268, surrounding the conductive connectors 272. The underfill material 276 may be any acceptable material, such as a polymer, epoxy, molding underfill, or the like, and provides mechanical support and protection for the electrical connections.

In some embodiments, the conductive connectors 272 may be ball grid array (BGA) connectors, solder balls, metal pillars, controlled collapse chip connection (C4) bumps, micro bumps, or the like. The conductive connectors 272 may include a conductive material such as solder, copper, aluminum, gold, nickel, silver, palladium, tin, the like, or a combination thereof. The conductive connectors 272 may be reflowed to couple the conductive connectors 272 to the first bond pads of the substrate 268 and bond pads 292 of the VRM 278. The conductive connectors 272 electrically and/or physically couple the substrate 268, including the first bond pads and metallization layers in the substrate 268, to the VRM 278.

The first package component 284 may be coupled to the voltage regulation site 298 of the structure 260 using conductive connectors 266 that are first formed on the UBMs 254 or the second bond pads of the substrate 268. The conductive connectors 266 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 266 may include a conductive material such as solder, copper, aluminum, gold, nickel, silver, palladium, tin, the like, or a combination thereof. In some embodiments, the conductive connectors 266 are formed by initially forming a layer of solder through evaporation, electroplating, printing, solder transfer, ball placement, or the like. Once a layer of solder has been formed on the structure, a reflow may be performed to shape the material into the desired bump shapes. Then the first package component 284 is mounted on the voltage regulation site 298 of the structure 260 such that the conductive connectors 266 are in physical contact with the UBMs 254 and the second bond pads of the substrate 268. In some embodiments, the conductive connectors 266 are then reflowed to attach the first package component 284 to structure 260 of the package structure 18. The conductive connectors 266 electrically and/or physically couple the structure 260 to the first package component 284. An underfill material 274 may be dispensed between the first package component 284 and the structure 260, surrounding the conductive connectors 266. The underfill material 274 may be any acceptable material, such as a polymer, epoxy, molding underfill, or the like, and provides mechanical support and protection for the electrical connections.

Referring further to FIG. 19, each second package component 282 may comprise a connector 280 that is coupled to a substrate 270 using the conductive connectors 272 (described above). The connector 280 may be, for example, a high-speed electrical interface component that comprises multiple signal pins and power pins arranged in a predetermined pattern. The connector 280 may include bond pads 294 on a bottom surface of the connector 280 that are used for electrical connection to the substrate 270 through the conductive connectors 272. The connector 280 may be configured to transmit and receive signals through the substrate 270 to enable communication between the integrated circuit dies 50 of the structure 260 of the package structure 18 and other external devices or to adjacent package structures within a larger system. In operation, the connector 280 may, for example, manage high-speed data transmission through the multiple signal pins, and provide input/output interfaces for signals, power, and ground connections while maintaining signal integrity for high-bandwidth communication between the package structure 18 and other external devices.

The substrate 270 may be similar to the substrate 268 that was described previously. For example, the substrate 270 may include a substrate core 293 and first bond pads over the substrate core 293, and second bond pads below the substrate core 293. The substrate core 293, and the first bonds and the second bonds of the substrate 270, may be formed using similar materials and process as the substrate core 291, and the first bonds and the second bonds of the substrate 268. The conductive connectors 272 may be reflowed to couple the conductive connectors 272 to the first bond pads of the substrate 270 and bond pads 294 of the connector 280. The conductive connectors 272 electrically and/or physically couple the substrate 270, including the first bond pads and metallization layers in the substrate 270, to the connector 280. The underfill material 276 (described above) may be dispensed between the connector 280 and the substrate 270, surrounding the conductive connectors 272.

The second package component 282 may be coupled to the connecting site 296 of the structure 260 using the conductive connectors 266 (described above). The conductive connectors 266 may be first formed on the UBMs 254 or the second bond pads of the substrate 270. Then the second package component 282 is mounted on the connecting site 296 of the structure 260 such that the conductive connectors 266 are in physical contact with the UBMs 254 and the second bond pads of the substrate 270. In some embodiments, the conductive connectors 266 are then reflowed to attach the second package component 282 to the structure 260 of the package structure 18. The conductive connectors 266 electrically and/or physically couple the structure 260 to the second package component 282. The underfill material 274 (described above) may be dispensed between the second package component 282 and the structure 260, surrounding the conductive connectors 266.

After the one or more first package components 284 are coupled to each of the voltage regulation sites 298, and the one or more second package components 282 are coupled to each of the connecting sites 296. the package structure 18 may be removed from the tape 262. The package structure 18 may include a first region 299 within which the integrated circuit dies 50 (which may include logic dies, memory dies, and/or I/O dies, or the like) and package components (e.g., the first package component 284 and the second package component 282) are disposed. As such, the first region 299 functions as an independent system with its own integrated circuit dies 50 (which may include logic dies, memory dies, and/or I/O dies, or the like) and package components (e.g., the first package component 284 and the second package component 282). The package structure 18 may be referred to as a system-on-panel (SOP) device.

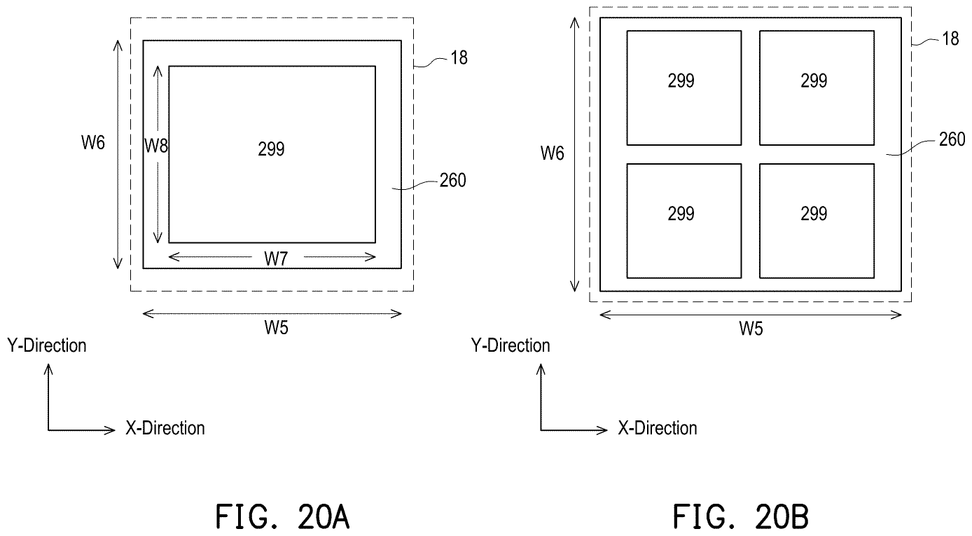

In FIG. 20A, a top-down view of the package structure 18 of FIG. 19 is shown according to an example embodiment. The package structure 18 may comprise the first region 299 in which the integrated circuit dies 50 and the package components (e.g., the first package components 284 and the second package components 282) of the package structure 18 are disposed. In an embodiment, the first region 299 may be a central region of the package structure 18. In an embodiment, the package structure 18 may have a rectangular shape when seen in a top-down view, wherein the package structure 18 has four straight outer edges (e.g., first parallel edges of the structure 260 oriented in the first direction (e.g., the x-direction), and second parallel edges of the structure 260 oriented in the second direction (e.g., the y-direction that is perpendicular to the first direction)). In an embodiment, each of the first parallel edges may have the width W5 that is greater than 252 mm, and each of the second parallel edges may have the width W6 that is greater than 252 mm. In an embodiment, when seen in a top-down view, a top surface of the structure 260 may have a surface area that is greater than 63,504 mm². In an embodiment, the first region 299 may have a width W7 in the first direction (e.g., the x-direction), wherein the width W7 is a distance in the first direction (e.g., the x-direction) between a first outermost sidewall of a first outermost one of the package components (e.g., a first outermost one of the first package components 284 or the second package components 282) and a second outermost sidewall of a second outermost one of the package components (e.g., a second outermost one of the first package components 284 or the second package components 282). In an embodiment, the first region 299 may have a width W8 in the second direction (e.g., the y-direction), wherein the width W8 is a distance in the second direction (e.g., the y-direction) between a third outermost sidewall of a third outermost one of the package components (e.g., a third outermost one of the first package components 284 or the second package components 282) and a fourth outermost sidewall of a fourth outermost one of the package components (e.g., a fourth outermost one of the first package components 284 or the second package components 282). In an embodiment, each of the width W5, the width W6, the width W7 and the width W8 may be greater than 212 mm. In an embodiment, when seen in a top-down view, a top surface of the structure 260 that is disposed in the first region 299 may have a surface area that is greater than 44,944 mm². In an embodiment, the width W5 may be up to 510 mm, and the width W6 may be up to 515 mm. In an embodiment, the width W6 may be up to 510 mm, and the width W5 may be up to 515 mm.

Advantages can be achieved by forming the package structure 18 having a rectangular shape when seen in a top-down view, wherein the rectangular shape of the package structure 18 has four straight outer edges (e.g., first parallel edges of the structure 260 oriented in the first direction (e.g., the x-direction), and second parallel edges of the structure 260 oriented in the second direction (e.g., the y-direction that is perpendicular to the first direction)). In an embodiment, each of the first parallel edges may have the width W5 that is greater than 252 mm, and each of the second parallel edges may have the width W6 that is greater than 252 mm. In addition, in a top-down view, the package structure 18 may comprise the first region 299 in which the integrated circuit dies 50 and the package components (e.g., the first package components 284 and the second package components 282) of the package structure 18 are disposed. The first region 299 may have the width W7 in the first direction (e.g., the x-direction), wherein the width W7 is a distance in the first direction (e.g., the x-direction) between a first outermost sidewall of a first outermost one of the package components (e.g., a first outermost one of the first package components 284 or the second package components 282) and a second outermost sidewall of a second outermost one of the package components (e.g., a second outermost one of the first package components 284 or the second package components 282). The first region 299 may have the width W8 in the second direction (e.g., the y-direction), wherein the width W8 is a distance in the second direction (e.g., the y-direction) between a third outermost sidewall of a third outermost one of the package components (e.g., a third outermost one of the first package components 284 or the second package components 282) and a fourth outermost sidewall of a fourth outermost one of the package components (e.g., a fourth outermost one of the first package components 284 or the second package components 282). In an embodiment, each of the width W7 and the width W8 may be greater than 212 mm.

These advantages include the rectangular shape (e.g., the edges of the structure 260) of the package structure 18 allowing for a reduction in edge area waste compared to round wafer formats because of the elimination of curved edges. As a result, the rectangular shape of the structure 260 can be formed to have a top surface with a larger surface area. In addition, the larger dimensions (e.g., the width W5 and the width W6 of the edges of the structure 260 being greater than 252 mm, and the width W7 and the width W8 of the first region 299 being greater than 212 mm) of the package structure 18 allow for the integration of more integrated circuit dies 50 and package components (e.g., the first package components 284 and the second package components 282) within the first region 299 of the package structure 18. This allows for increased design flexibility and reduces or eliminates the need for system-level interconnects between multiple smaller packages. As a result, device performance may be enhanced through reduced signal path lengths between components of the package structure 18, and improved power delivery can be achieved through the integration of additional first package components 284 (e.g., that include the VRMs 278) for high-performance computing applications.

In FIG. 20B, a top-down view of the package structure 18 is shown according to an example embodiment. The package structure 18 may comprise four first regions 299 arranged in a 2×2 array configuration, wherein each first region 299 functions as an independent system with its own integrated circuit dies 50 (which may include logic dies, memory dies, and/or I/O dies) and package components (e.g., the first package components 284 and the second package component 282). As such, the package structure 18 may be referred to as a system-on-panel (SOP) device. In an embodiment, the package structure 18 may have a rectangular shape when seen in a top-down view, wherein the package structure 18 has four straight outer edges (e.g., first parallel edges oriented in the first direction (e.g., the x-direction), and second parallel edges oriented in the second direction (e.g., the y-direction that is perpendicular to the first direction)). In an embodiment, each of the first parallel edges may have the width W5 that is greater than 252 mm, and each of the second parallel edges may have the width W6 that is greater than 252 mm. In an embodiment, when seen in a top-down view, a top surface of the structure 260 may have a surface area that is greater than 63,504 mm². In an embodiment, the width W5 may be up to 510 mm, and the width W6 may be up to 515 mm. In an embodiment, the width W6 may be up to 510 mm, and the width W5 may be up to 515 mm.

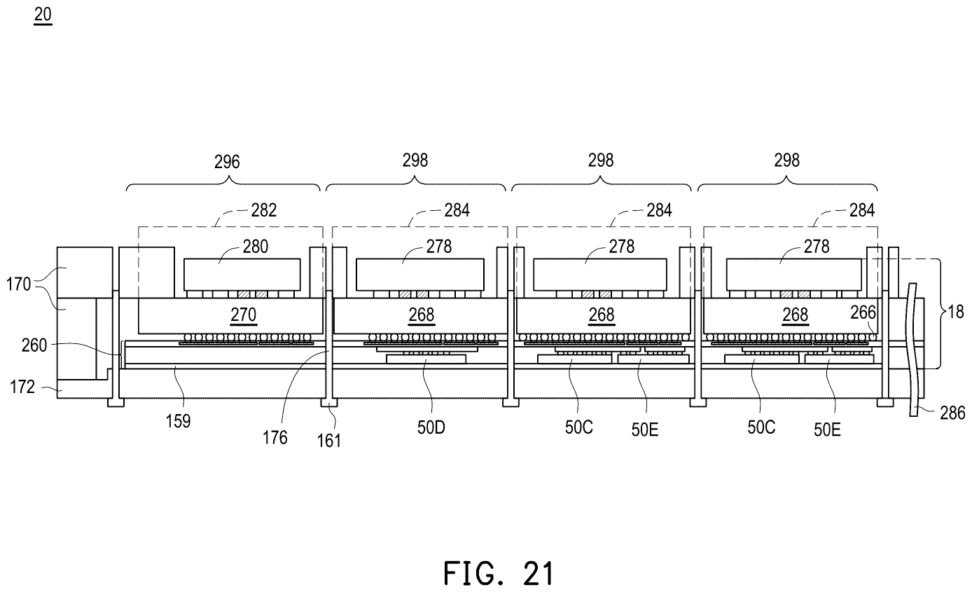

FIG. 21 illustrates the integration and assembly of an example package structure 18 with various assembly components to form a system 20, in accordance with some embodiments. Unless specified otherwise, like reference numerals in this embodiment represent like components in the embodiment shown in FIGS. 1 through 20B formed by like processes. Accordingly, the process steps and applicable materials may not be repeated herein. The system 20 may be configured to support and enable operation of the package structure 18 in, for example, a high-performance computing environment, or the like. For example, the system 20 may provide mechanical support, thermal management, and electrical connections to allow the package structure 18 to function as an integrated computing system.

The package structure 18 shown in the embodiment of FIG. 21 may be different from the package structure 18 shown in the embodiment of FIG. 19 in that the package structure 18 shown in the embodiment of FIG. 21 may include a plurality of voltage regulation sites 298 and a plurality of connecting sites 296, wherein the package structure 18 may include regions beyond the divider 286 that are not shown in the FIG. 21. A first package component 284 (described previously in FIG. 19) is coupled to each of the voltage regulation sites 298, and a second package component 282 (described previously in FIG. 19) is coupled to each of the connecting sites 296. In an embodiment, a first VRM 278 may be disposed over and electrically connected to an I/O interface die 50D in a first voltage regulation site 298. The first VRM 278 may be configured to receive input power through a first substrate 268 and provide regulated output voltages to the I/O interface die 50D. In an embodiment, a second VRM 278 may be disposed over and electrically connected to a first SoC die 50C and a first high bandwidth memory (HBM) die 50E in a second voltage regulation site 298. The second VRM 278 may be configured to receive input power through a second substrate 268 and provide regulated output voltages to the first SoC die 50C and the first high bandwidth memory (HBM) die 50E. In addition, a third VRM 278 may be disposed over and electrically connected to a second SoC die 50C and a second high bandwidth memory (HBM) die 50E in a third voltage regulation site 298. The third VRM 278 may be configured to receive input power through a third substrate 268 and provide regulated output voltages to the second SoC die 50C and the second high bandwidth memory (HBM) die 50E.

Referring further to FIG. 21, the package structure 18 may be positioned in a space between a cold plate 172 (described previously in FIGS. 12 and 13) and an Input/Output (IO) frame 170 (described previously in FIGS. 12 and 13). During the positioning, a support fixture (not shown in the Figures) may be used to hold and support the package structure 18, the cold plate 172, and the IO frame 170. The support fixture may ensure accurate alignment of the IO frame 170, package structure 18, and cold plate 172 relative to each other before final assembly of the system 20. For example, the cold plate 172 may first be positioned on the support fixture, such that the support fixture supports the cold plate 172. The cold plate 172 may be a thermal management structure that comprises a thermally conductive material (e.g., copper, aluminum, or the like) to dissipate heat from the package structure 18 during operation of the system 20. In an embodiment, before placing the package structure 18 on the cold plate 172, a thermal interface material (TIM) 159 may be dispensed on the back side of the package structure 18, to physically and thermally couple the cold plate 172 to the integrated circuit dies 50 and the encapsulant 250. The TIM 159 may be a film comprising indium, a thermal grease, a thermal sheet, a phase change material, the like, or a combination thereof.

The IO frame 170 may then be positioned over the package structure 18 and the cold plate 172. The IO frame 170 may be a structural support component that comprises a rigid material (e.g., metal, reinforced polymer, or the like) to provide mechanical support for the package structure 18 during operation of the system 20. The IO frame 170 may comprise a top portion having openings arranged in a predetermined pattern for accessing the VRMs 278 and connector 280 of the package structure 18. The IO frame 170 may also comprise bottom portions that extend downwards from edges of the top portion of the IO frame 170. In an embodiment, the top portion and the bottom portions of the IO frame 170 may surround the package structure 18, such that a portion of the package structure 18 is disposed between inner sidewalls of the bottom portions of the IO frame 170. In an embodiment, the bottom portions of the IO frame 170 are aligned with and in contact with top surfaces of edge portions of the cold plate 172, such that the space between the cold plate 172 and the IO frame 170 is formed. In an embodiment, screw holes may extend through the top portion of the IO frame 170 and the cold plate 172, wherein the screw holes of the top portion of the IO frame 170 and the cold plate 172 are aligned with screw holes 264 (described previously in FIG. 19) in the package structure 18. In an embodiment, the top portion of the IO frame 170 may be in contact with top surfaces of the package structure 18 (e.g., top surfaces of the substrates 270 and 268).

Referring further to FIG. 21, the package structure 18 may be fastened between the IO frame 170 and the cold plate 172 using screws 176 to form the system 20. The screws may be inserted through the screw holes in the top portion of the IO frame 170, through the screw holes 264 of the package structure 18, and through corresponding screw holes in the cold plate 172. Fasteners 161 may be threaded onto the screws 176 and tightened to clamp the package structure 18 between the IO frame 170 and cold plate 172. The fasteners 161 may be, e.g., nuts that thread to the screws 176 at opposite ends of each screw 176. During the fastening process, the fasteners 161 may be tightened to apply enough mechanical force to secure the package structure 18 between the IO frame 170 and the cold plate 172, ensuring proper mechanical support and thermal contact between the cold plate 172 and the package structure 18. After the package structure 18 is fastened between the IO frame 170 and the cold plate 172 to form the system 20, the system 20 may be removed from the support fixture.

The embodiments of the present disclosure have some advantageous features. The embodiments include forming a device package (e.g., a system-on-panel (SOP) device) that comprises a redistribution structure that has one or more semiconductor chips bonded to the redistribution structure and one or more package components bonded to a side of the redistribution structure opposing the one or more semiconductor chips. The one or more semiconductor chips may be surrounded by an encapsulant, and the combination of the encapsulant and the redistribution structure may be referred to as a panel. In a top-down view, the panel may have a rectangular shape with four straight edges (e.g., including first parallel edges oriented in a first direction, and second parallel edges oriented in a second direction that is perpendicular to the first direction), wherein a distance between the first parallel edges or the second parallel edges is greater than 252 mm, and wherein a distance between the first parallel edges is up to 510 mm, and wherein a distance between the second parallel edges is up to 515 mm. One or more embodiments disclosed herein may allow for the rectangular shape of the panel to reduce the amount of edge area waste as compared to round wafer formats. The rectangular shape maximizes usable area by eliminating the curved edges present in round wafer formats, thereby enabling more efficient utilization of the panel. In addition, the larger dimensions of the panel may enable the integration of more semiconductor chips and package components in a single package. This increased integration capacity provides greater design flexibility and may reduce or eliminate the use of system-level interconnects between multiple smaller packages. As a result, device performance is enhanced through reduced signal path lengths and improved power delivery for high-performance computing applications.

In accordance with an embodiment, a method includes forming a package structure, where forming the package structure includes attaching a plurality of dies to a carrier substrate; performing an encapsulation process to surround the plurality of dies with an encapsulant; and forming a redistribution structure over the plurality of dies and the encapsulant, where the redistribution structure is electrically connected to the plurality of dies, wherein the redistribution structure has a rectangular shape when seen in a top-down view, where the rectangular shape has first parallel edges having a first width, and second parallel edges having a second width, where at least one of the first width and the second width is greater than 212 mm. In an embodiment, performing the encapsulation process includes applying a granulated molding compound on and around the plurality of dies and over the carrier substrate. In an embodiment, forming the redistribution structure includes performing a slit coating process to form a dielectric layer of the redistribution structure over the encapsulant and the plurality of dies. In an embodiment, forming the package structure further includes forming screw holes that extend through the redistribution structure and the encapsulant. In an embodiment, forming the package structure further includes coupling a voltage regulation module (VRM) and a connector to the redistribution structure; and forming an underfill in a gap between the VRM and the redistribution structure, and in a gap between the connector and the redistribution structure. In an embodiment, the method further includes positioning the package structure in a space between a cold plate and an Input/Output (IO) frame; and fastening the package structure to the cold plate and the IO frame using screws that extend through the screw holes in the redistribution structure and the encapsulant. In an embodiment, where the first width is up to 510 mm and the second width is up to 515 mm.

In accordance with an embodiment, a method of forming a system includes forming a package structure, where forming the package structure includes forming a first portion of the package structure, where forming the first portion of the package structure includes forming a back-side redistribution structure over a carrier substrate; attaching a first plurality of dies to the back-side redistribution structure; performing a first encapsulation process to surround the first plurality of dies with a first encapsulant; forming a front-side redistribution structure over the first plurality of dies and the first encapsulant; attaching a second plurality of dies to the front-side redistribution structure; and performing a second encapsulation process to surround the second plurality of dies with a second encapsulant, where the first portion of the package structure has a rectangular shape when seen in a top-down view, where the rectangular shape has first parallel edges having a first width, and second parallel edges having a second width, where at least one of the first width and the second width is greater than 212 mm. In an embodiment, performing the first encapsulation process includes applying a granulated molding compound on and around the first plurality of dies and over the back-side redistribution structure. In an embodiment, forming the first portion of the package structure further includes forming conductive vias over and electrically connected to the back-side redistribution structure. In an embodiment, the first plurality of dies includes at least one bridge die. In an embodiment, the first plurality of dies includes at least one integrated voltage regulator (IVR) die. In an embodiment, forming the package structure further includes coupling a first package component to a voltage regulation site of the first portion of the package structure, where the first package component includes a first substrate and a voltage regulation module (VRM) that is coupled to the first substrate. In an embodiment, forming the package structure further includes coupling a second package component to a connecting site of the first portion of the package structure, where the second package component includes a second substrate and a connector that is coupled to the second substrate.

In accordance with an embodiment, a system includes a package structure including a plurality of dies coupled to a first side of a redistribution structure; and an encapsulant on the first side of the redistribution structure, where the encapsulant surrounds each of the plurality of dies, where the package structure has a rectangular shape in a top-down view, where the rectangular shape has first parallel edges having a first width, and second parallel edges having a second width, and where at least one of the first width and the second width is greater than 212 mm. In an embodiment, the package structure further includes a voltage regulation module (VRM) and a connector coupled to a second side of the redistribution structure. In an embodiment, the encapsulant includes a granulated molding compound. In an embodiment, the system further includes a thermal module disposed below and in contact with the package structure; and an Input/Output (IO) frame disposed above the package structure, where the package structure is disposed in a space between the thermal module and the IO frame. In an embodiment, the system further includes screws extending through screw holes in the thermal module, the IO frame, and the redistribution structure; and fasteners that are threaded onto ends of the screws, where the screws and the fasteners secure the package structure between the thermal module and the IO frame. In an embodiment, the thermal module is a cold plate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a package structure, wherein forming the package structure comprises:
attaching a plurality of dies to a carrier substrate;
performing an encapsulation process to surround the plurality of dies with an encapsulant; and
forming a redistribution structure over the plurality of dies and the encapsulant, wherein the redistribution structure is electrically connected to the plurality of dies, wherein the redistribution structure has a rectangular shape when seen in a top-down view, wherein the rectangular shape has first parallel edges having a first width, and second parallel edges having a second width, wherein at least one of the first width and the second width is greater than 212 mm.

2. The method of claim 1, wherein performing the encapsulation process comprises applying a granulated molding compound on and around the plurality of dies and over the carrier substrate.

3. The method of claim 2, wherein forming the redistribution structure comprises performing a slit coating process to form a dielectric layer of the redistribution structure over the encapsulant and the plurality of dies.

4. The method of claim 1, wherein forming the package structure further comprises:
forming screw holes that extend through the redistribution structure and the encapsulant.

5. The method of claim 4, wherein forming the package structure further comprises:
coupling a voltage regulation module (VRM) and a connector to the redistribution structure; and
forming an underfill in a gap between the VRM and the redistribution structure, and in a gap between the connector and the redistribution structure.

6. The method of claim 5, further comprising:
positioning the package structure in a space between a cold plate and an Input/Output (IO) frame; and
fastening the package structure to the cold plate and the IO frame using screws that extend through the screw holes in the redistribution structure and the encapsulant.

7. The method of claim 1, wherein the first width is up to 510 mm and the second width is up to 515 mm.

8. A method of forming a system, the method comprising:
forming a package structure, wherein forming the package structure comprises:
forming a first portion of the package structure, wherein forming the first portion of the package structure comprises:
forming a back-side redistribution structure over a carrier substrate; attaching a first plurality of dies to the back-side redistribution structure;
performing a first encapsulation process to surround the first plurality of dies with a first encapsulant;
forming a front-side redistribution structure over the first plurality of dies and the first encapsulant;
attaching a second plurality of dies to the front-side redistribution structure; and
performing a second encapsulation process to surround the second plurality of dies with a second encapsulant, wherein the first portion of the package structure has a rectangular shape when seen in a top-down view, wherein the rectangular shape has first parallel edges having a first width, and second parallel edges having a second width, wherein at least one of the first width and the second width is greater than 212 mm.

9. The method of claim 8, wherein performing the first encapsulation process comprises applying a granulated molding compound on and around the first plurality of dies and over the back-side redistribution structure.

10. The method of claim 8, wherein forming the first portion of the package structure further comprises:
forming conductive vias over and electrically connected to the back-side redistribution structure.

11. The method of claim 8, wherein the first plurality of dies comprises at least one bridge die.

12. The method of claim 11, wherein the first plurality of dies comprises at least one integrated voltage regulator (IVR) die.

13. The method of claim 8, wherein forming the package structure further comprises:
coupling a first package component to a voltage regulation site of the first portion of the package structure, wherein the first package component comprises a first substrate and a voltage regulation module (VRM) that is coupled to the first substrate.

14. The method of claim 13, wherein forming the package structure further comprises:
coupling a second package component to a connecting site of the first portion of the package structure, wherein the second package component comprises a second substrate and a connector that is coupled to the second substrate.

15. A system comprising:
a package structure comprising:
a plurality of dies coupled to a first side of a redistribution structure; and
an encapsulant on the first side of the redistribution structure, wherein the encapsulant surrounds each of the plurality of dies, wherein the package structure has a rectangular shape in a top-down view, wherein the rectangular shape has first parallel edges having a first width, and second parallel edges having a second width, and wherein at least one of the first width and the second width is greater than 212 mm.

16. The system of claim 15, wherein the package structure further comprises:
a voltage regulation module (VRM) and a connector coupled to a second side of the redistribution structure.

17. The system of claim 15, wherein the encapsulant comprises a granulated molding compound.

18. The system of claim 15, further comprising:
a thermal module disposed below and in contact with the package structure; and
an Input/Output (IO) frame disposed above the package structure, wherein the package structure is disposed in a space between the thermal module and the IO frame.

19. The system of claim 18, further comprising:
screws extending through screw holes in the thermal module, the IO frame, and the redistribution structure; and
fasteners that are threaded onto ends of the screws, wherein the screws and the fasteners secure the package structure between the thermal module and the IO frame.

20. The system of claim 19, wherein the thermal module is a cold plate.
